(19) United States
(12) Patent Application Publication
(10) Pub. No.: US 2023/0106038 A1
(43) Pub. Date: Apr. 6, 2023

(54) IMAGE SENSOR AND METHOD OF FABRICATING THE SAME

(71) Applicant: Samsung Electronics Co., Ltd., Suwon-si (KR)

(72) Inventors: Sena SHIM, Seoul (KR); Youngtak KIM, Hwaseong-si (KR); Jaeuk SHIN, Suwon-si (KR); Jinyoung KIM, Suwon-si (KR); Tae-Hun LEE, Suwon-si (KR)

(21) Appl. No.: 17/865,478

(22) Filed: Jul. 15, 2022

(30) Foreign Application Priority Data
Oct. 1, 2021 (KR) 10-2021-0131057

(51) Int. Cl. H01L 27/146

(52) U.S. Cl. CPC H01L 27/14698; H01L 27/1463; H01L 27/14623; H01L 27/14685; H01L 27/14643

(57) ABSTRACT

A method of fabricating an image sensor includes providing a semiconductor substrate having a first surface and a second surface that are opposite to each other. A mask pattern is formed on the first surface. The mask pattern has an opening. A first fluid is supplied in the opening. The first fluid is vaporized to remove the first fluid on the semiconductor substrate. An etching process is performed using the mask pattern to form a pixel isolation trench extending from the first surface towards the second surface. A second fluid is supplied in the pixel isolation trench. The second fluid is replaced in the pixel isolation trench with a third fluid. The third fluid is vaporized. The third fluid has a surface tension that is lower than a surface tension of the first fluid.

### CROSS-REFERENCE TO RELATED APPLICATIONS

This application claims priority under 35 U.S.C. § 119 to Korean Patent Application No. 10-2021-0131057, filed on Oct. 1, 2021 in the Korean Intellectual Property Office, the disclosure of which is incorporated by reference in its entirety herein.

### 1. TECHNICAL FIELD

The present inventive concept relates to an image sensor and a method of fabricating the same, and in particular, to an image sensor with increased electrical and optical characteristics and a method of fabricating the same.

### 2. DISCUSSION OF RELATED ART

An image sensor is a device that converts optical signals into electrical signals. As the computer and communications industries have developed, there is an increasing demand for high-performance image sensors in a variety of applications such as digital cameras, camcorders, personal communication systems, gaming machines, security cameras, micro-cameras for medical applications, and/or robots.

Image sensors are generally classified into charge-coupled device (CCD) and complementary metal-oxide semiconductor (CMOS) image sensors. The CMOS image sensor can be operated in a simplified manner. Additionally, since signal-processing circuits of the CMOS image sensor can be integrated on a single chip, it is possible to reduce a size of a product that the CMOS image sensor is applied to. In addition, since the CMOS image sensor can be operated with a relatively low power consumption, it can be easily applied to an electronic device with a limited battery capacity. Furthermore, since the CMOS image sensor can be fabricated using existing CMOS fabrication techniques, it is possible to reduce a manufacturing cost thereof. With the development of CMOS image sensors having a high resolution, the use of CMOS image sensors is rapidly increasing.

### SUMMARY

An embodiment of the present inventive concept provides a method of fabricating an image sensor with a low process failure and a high pixel density.

An embodiment of the present inventive concept provides an image sensor, which can be easily fabricated and has an increased pixel density per unit area.

According to an embodiment of the present inventive concept, a method of fabricating an image sensor includes providing a semiconductor substrate having a first surface and a second surface that are opposite to each other. A mask pattern is formed on the first surface. The mask pattern has an opening. A first fluid is supplied in the opening. The first fluid is vaporized to remove the first fluid on the semiconductor substrate. An etching process is performed using the mask pattern to form a pixel isolation trench extending from the first surface towards the second surface. A second fluid is supplied in the pixel isolation trench. The second fluid is replaced in the pixel isolation trench with a third fluid. The third fluid is vaporized. The third fluid has a surface tension that is lower than a surface tension of the first fluid.

According to an embodiment of the present inventive concept, a method of fabricating an image sensor includes performing an etching process on a semiconductor substrate to form a pixel isolation trench that defines pixel regions. A cleaning process is performed using a cleaning solution in the pixel isolation trench. The cleaning solution is removed and a first fluid is supplied in the pixel isolation trench. The semiconductor substrate is loaded in a drying chamber and a second fluid is supplied in a supercritical state onto the first fluid. The first fluid and the second fluid are removed in the pixel isolation trench by lowering an internal pressure of the drying chamber. An ion implantation process is performed in the pixel isolation trench.

According to an embodiment of the present inventive concept, an image sensor, includes a semiconductor substrate having a first surface and a second surface that are opposite to each other in a first direction. A pixel isolation structure extends in the first direction between the first surface and the second surface to define a plurality of pixel regions. The pixel isolation structure comprises a first portion and a second portion that are spaced apart from each other with a first pixel region of the plurality of pixel regions interposed therebetween in a second direction perpendicular to the first direction. The image sensor has a G-factor in a range of about 1200 to about 2200. The G-factor is determined by Formula 1. Formula 1 is G=(h⁴/t³d²) in which G is the G-factor, h is a length of the first portion in the first direction, t is a distance between the first and second portions in the second direction, and d is a largest width of the first portion in the second direction.

### BRIEF DESCRIPTION OF THE DRAWINGS

FIG. 1 is a block diagram illustrating an image sensor according to an embodiment of the present inventive concept.

FIG. 2 is a circuit diagram illustrating an active pixel sensor array of an image sensor according to an embodiment of the present inventive concept.

FIG. 3 is a plan view illustrating an image sensor according to an embodiment of the present inventive concept.

FIG. 4 is a cross-sectional view of an image sensor taken along a line I-I′ of FIG. 3 according to an embodiment of the present inventive concept.

FIG. 5 is an enlarged cross-sectional view illustrating a portion AA of FIG. 4 according to an embodiment of the present inventive concept.

FIGS. 6 and 7 are cross-sectional views illustrating an image sensor according to embodiments of the present inventive concept.

FIG. 8 is a diagram schematically illustrating a wet treatment system which is used in a process of fabricating an image sensor according to an embodiment of the present inventive concept.

FIG. 9 is a diagram schematically illustrating a drying system which is used in the process of fabricating an image sensor according to an embodiment of the present inventive concept.

FIG. 10 is a flow chart illustrating a method of forming a pixel isolation structure, according to an embodiment of the present inventive concept.

FIG. 11 is a flow chart illustrating a second cleaning process and a second drying process, according to an embodiment of the present inventive concept.

FIGS. 12A to 12S are cross-sectional views taken along a line I-I′ of FIG. 3, illustrating a method of fabricating an image sensor according to embodiments of the present inventive concept.

FIGS. 13A and 13B are graphs showing the number of leaning issues per wafer versus G-factor.

FIG. 14 is a plan view schematically illustrating an image sensor including a semiconductor device, according to an embodiment of the present inventive concept.

FIG. 15 is a cross-sectional view taken along a line II-II′ of FIG. 14 illustrating an image sensor according to an embodiment of the present inventive concept.

### DETAILED DESCRIPTION OF EMBODIMENTS

Embodiments of the present inventive concept will now be described more fully with reference to the accompanying drawings, in which embodiments are shown.

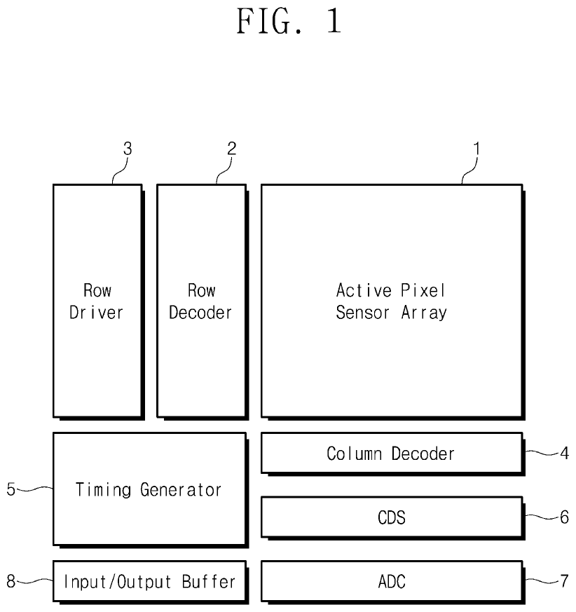

FIG. 1 is a block diagram illustrating an image sensor according to an embodiment of the present inventive concept.

Referring to FIG. 1, an image sensor may include an active pixel sensor array 1, a row decoder 2, a row driver 3, a column decoder 4, a timing generator 5, a correlated double sampler (CDS) 6, an analog-to-digital converter (ADC) 7, and an input/output buffer 8.

The active pixel sensor array 1 may include a plurality of two-dimensionally arranged unit pixels, each of which is configured to convert optical signals into electrical signals. The active pixel sensor array 1 may be driven by a plurality of driving signals, such as a pixel selection signal, a reset signal, and a charge transfer signal, which are transmitted from the row driver 3. The converted electrical signal may be provided to the correlated double sampler 6.

The row driver 3 may be configured to provide the driving signals for driving the plurality of unit pixels to the active pixel sensor array 1, based on the result decoded by the row decoder 2. In an embodiment in which the unit pixels are arranged in a matrix shape (e.g., in rows and columns), the driving signals may be provided to respective rows.

The timing generator 5 may be configured to provide timing and control signals to the row decoder 2 and the column decoder 4.

The correlated double sampler 6 may be configured to receive the electric signals generated in the active pixel sensor array 1 and then to perform an operation of holding and sampling the received electric signals. The correlated double sampler 6 may perform a double sampling operation, in which a specific noise level and a signal level of the electric signal are used, and then may output a difference level corresponding to a difference between the noise and signal levels.

The analog-to-digital converter 7 may be configured to convert analog signals, which correspond to the difference level output from the correlated double sampler 6, into digital signals, and then to output the converted digital signals to the input/output buffer 8.

The input/output buffer 8 may be configured to latch the digital signal and to sequentially output the latched digital signals to an image signal processing unit, based on the result decoded by the column decoder 4.

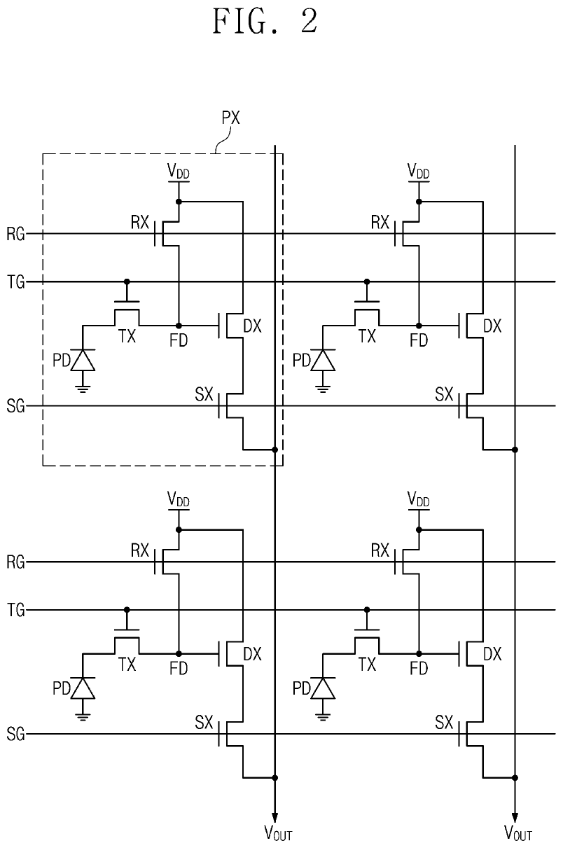

FIG. 2 is a circuit diagram illustrating an active pixel sensor array of an image sensor according to an embodiment of the present inventive concept.

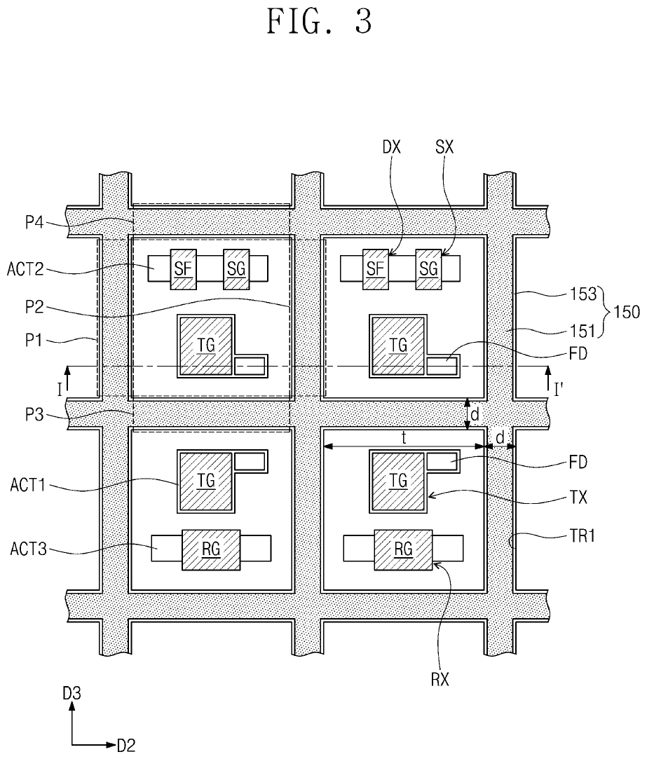

Referring to FIGS. 1 and 2, the active pixel sensor array 1 may include a plurality of unit pixels PX, which are arranged in a matrix shape. Each of the unit pixels PX may include a transfer transistor TX and logic transistors RX, SX, and DX. The logic transistors may include a reset transistor RX, a selection transistor SX, and a drive transistor DX. The transfer transistor TX may include a transfer gate TG (FIG. 3). Each of the unit pixels PX may further include a photoelectric conversion device PD and a floating diffusion region FD.

The photoelectric conversion device PD may be configured to generate photocharges in which the levels of the photocharges are proportional to an amount of externally incident light. The photoelectric conversion device PD may store the photocharges. In an embodiment, the photoelectric conversion device PD may include a photo diode, a photo transistor, a photo gate, a pinned photo diode, or any combination thereof. The transfer transistor TX may be configured to transfer electric charges, which are generated in the photoelectric conversion device PD, to the floating diffusion region FD. The floating diffusion region FD may be configured to receive the charges, which are generated in the photoelectric conversion device PD, and to cumulatively store the charges therein. The drive transistor DX may be controlled by an amount of the photocharges to be stored in the floating diffusion region FD.

The reset transistor RX may be configured to periodically discharge the photocharges stored in the floating diffusion region FD. The reset transistor RX may include a drain electrode, which is connected to the floating diffusion region FD, and a source electrode, which is connected to a power voltage VDD. When the reset transistor RX is turned on, the power voltage VDD may be applied to the floating diffusion region FD through the source electrode of the reset transistor RX. Accordingly, the electric charges stored in the floating diffusion region FD may be discharged through the reset transistor RX, and as a result, the floating diffusion region FD may be in a reset state.

The drive transistor DX may serve as a source follower buffer amplifier. The drive transistor DX may be used to amplify a variation in electric potential of the floating diffusion region FD and to output the amplified signal to an output line Vout.

The selection transistor SX may be used to select each row of the unit pixels PX for a read operation. When the selection transistor SX is turned on, the power voltage VDD may be applied to a drain electrode of the drive transistor DX.

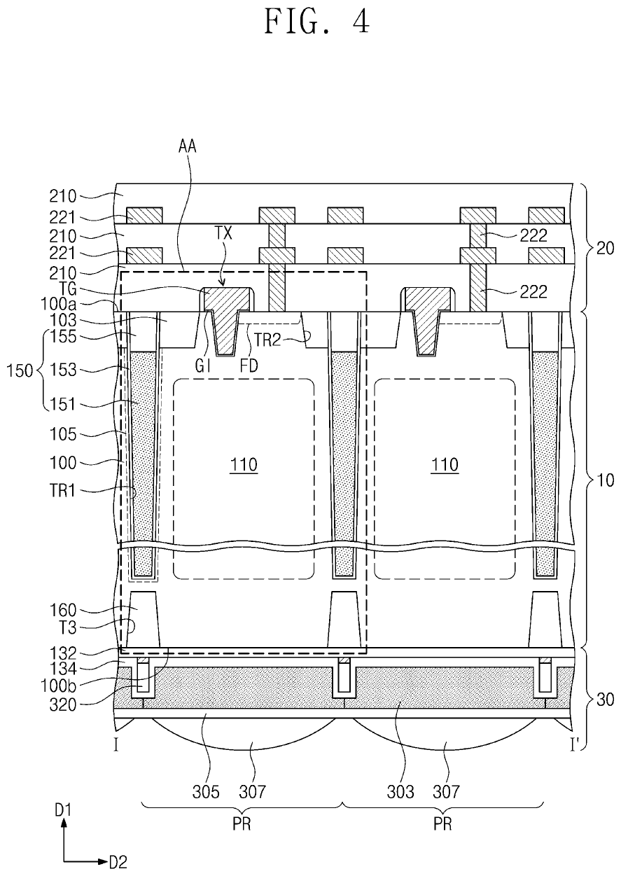

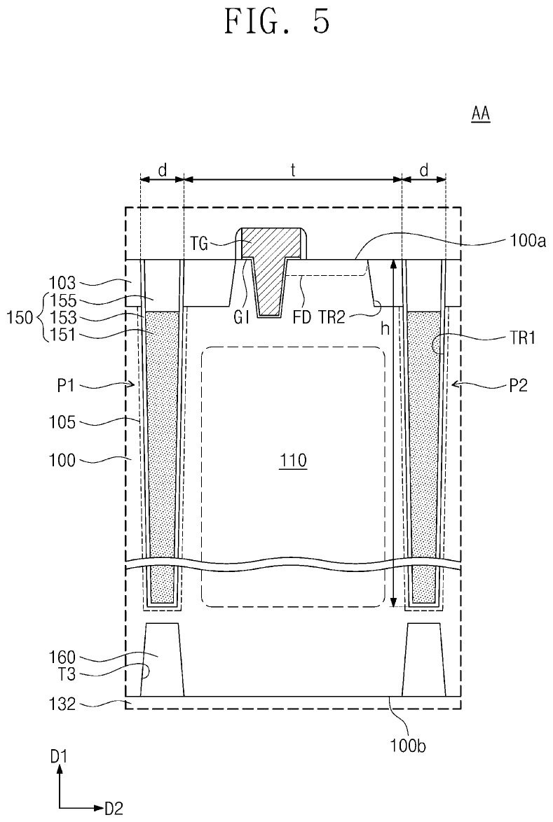

FIG. 3 is a plan view illustrating an image sensor according to an embodiment of the present inventive concept. FIG. 4 is a cross-sectional view taken along a line I-I′ of FIG. 3. FIG. 5 is an enlarged cross-sectional view illustrating a portion AA of FIG. 4.

Referring to FIGS. 3 to 5, an image sensor according to an embodiment of the present inventive concept may include a photoelectric conversion layer 10, a readout circuit layer 20, and an optically-transparent layer 30.

The photoelectric conversion layer 10 may be disposed between the readout circuit layer 20 and the optically-transparent layer 30 (e.g., in the first direction D1 which is a thickness direction of a semiconductor substrate 100). The photoelectric conversion layer 10 may receive light that is incident through the optically-transparent layer 30. The photoelectric conversion layer 10 may convert the received light to an electrical signal. The photoelectric conversion layer 10 may include the semiconductor substrate 100, a pixel isolation structure 150, an auxiliary isolation structure 160, and photoelectric conversion regions 110.

The semiconductor substrate 100 may have a first surface 100a and a second surface 100b, which are opposite to each other in the first direction D1. The first surface 100a may face the readout circuit layer 20, and the second surface 100b may face the optically-transparent layer 30. The semiconductor substrate 100 may have a first conductivity type (e.g., p-type). For example, the semiconductor substrate 100 may include a bulk silicon portion and an epitaxial layer, which is formed on the bulk silicon portion and has the first conductivity type. In an embodiment, the bulk silicon portion may be removed in a process of fabricating an image sensor, and as a result, the semiconductor substrate 100 may include only an epitaxial layer. In an embodiment, the semiconductor substrate 100 may be a bulk silicon substrate, in which a well of the first conductivity type is formed.

The semiconductor substrate 100 may include a plurality of pixel regions PR, which are defined by the pixel isolation structure 150. The pixel regions PR may be arranged in a matrix shape or in a second direction D2 and a third direction D3, which are not parallel to each other. For example, in an embodiment, the second direction D2 and the third direction D3 may be perpendicular to each other and may both be perpendicular to the first direction D1. However, embodiments of the present inventive concept are not necessarily limited thereto. The pixel regions PR may correspond to the unit pixels PX, respectively, of FIGS. 1 and 2. The pixel isolation structure 150 may be extended in the first direction D1, between the first and second surfaces 100a and 100b of the semiconductor substrate 100. The pixel isolation structure 150 may be provided between the pixel regions PR to separate the pixel regions PR electrically and physically from each other. The pixel isolation structure 150 may prevent light, which is incident into each pixel region PR, from traveling toward neighboring pixel regions PR. In addition, the pixel isolation structure 150 may prevent photocharges, which are generated by light incident into each pixel region PR, from being leaked to the neighboring pixel regions PR.

In an embodiment, the pixel isolation structure 150 may have a lattice structure, when viewed in a plan view (e.g., in a plane in the second and third directions D2, D3). For example, the pixel isolation structure 150 may include first line portions, which are extended in the second direction D2 and parallel to each other, and second line portions, which are extended in the third direction D3 to be parallel to each other and to cross the first line portions. The pixel isolation structure 150 may be provided to enclose each of the pixel regions PR, when viewed in a plan view. The pixel isolation structure 150 may be provided in a pixel isolation trench TR1, which is formed by recessing, the first surface 100a of the semiconductor substrate 100. In an embodiment, a width of the pixel isolation trench TR1 may gradually decrease along a direction from the first surface 100a of the semiconductor substrate 100 towards the second surface 100b.

The pixel isolation structure 150 may include an insulating pattern 153, a conductive pattern 151, and a capping pattern 155. The insulating pattern 153 may be provided to cover an inner surface of the pixel isolation trench TR1. The insulating pattern 153 may be extended from the first surface 100a of the semiconductor substrate 100 toward the second surface 100b. The insulating pattern 153 may be arranged to enclose each of the photoelectric conversion regions 110, when viewed in a plan view. The insulating pattern 153 may be in direct contact with the semiconductor substrate 100. In an embodiment, the insulating pattern 153 may be formed of or include a material having a refractive index that is lower than the refractive index of the semiconductor substrate 100. For example, in an embodiment, the insulating pattern 153 may be formed of or include at least one compound selected from silicon nitride, silicon oxide, and silicon oxynitride. The insulating pattern 153 may be formed of or include at least one of high-k dielectric materials (e.g., hafnium oxide and aluminum oxide). In an embodiment, the insulating pattern 153 may include a plurality of layers including various materials.

The conductive pattern 151 may be arranged to fill a lower portion of the pixel isolation trench TR1. The conductive pattern 151 may be spaced apart from the semiconductor substrate 100 with the insulating pattern 153 interposed therebetween. For example, the conductive pattern 151 may be electrically disconnected from the semiconductor substrate 100 by the insulating pattern 153. A top surface of the conductive pattern 151 may be located at a level lower than the first surface 100a of the semiconductor substrate 100. The conductive pattern 151 may be formed of or include a semiconductor material. For example, the conductive pattern 151 may be formed of or include poly silicon. In an embodiment, the conductive pattern 151 may contain dopants of a first conductivity type. For example, in an embodiment the conductive pattern 151 may contain at least one compound selected from boron (B), phosphorus (P), arsenic (As), gallium (Ga), indium (In), antimony (Sb), and aluminum (Al).

The capping pattern 155 may be provided to fill a remaining portion of the pixel isolation trench TR1 provided with the insulating and conductive patterns 153 and 151. The capping pattern 155 may be placed in an upper portion of the pixel isolation trench TR1. A top surface of the capping pattern 155 may be coplanar (e.g., in the first direction D1) with the first surface 100a of the semiconductor substrate 100. In an embodiment, the capping pattern 155 may be formed of or include at least one compound selected from silicon oxide, silicon oxynitride, and silicon nitride.

The pixel isolation structure 150 may separate one of the pixel regions PR from the adjacent pixel regions PR. The pixel isolation structure 150 may include a first portion P1, a second portion P2, a third portion P3, and a fourth portion P4, which are arranged to enclose one pixel region PR, as shown in FIG. 3. In an embodiment, the first to fourth portions P1, P2, P3, and P4 may be arranged to enclose the pixel region PR in a rectangular or square shape, when viewed in a plan view. The first and second portions P1 and P2 may be spaced apart from each other in the second direction D2, with the pixel region PR interposed therebetween. The first and second portions P1 and P2 may be extended in the third direction D3 and parallel to each other. The third and fourth portions P3 and P4 may be spaced apart from each other in the third direction D3, with the pixel region PR interposed therebetween. The third and fourth portions P3 and P4 may be extended in the second direction D2 and parallel to each other. Each of the first to fourth portions P1, P2, P3, and P4 of the pixel isolation structure 150 may have a rectangular shape, when viewed in a plan view. In an embodiment, each of the first to fourth portions P1, P2, P3, and P4 may have the same width d, when measured in a short axis direction thereof that is perpendicular to the longitudinally extending direction thereof.

In an embodiment, the width d of each of the first and second portions P1 and P2 in the second direction D2 may decrease as a distance to the second surface 100b decreases. In an embodiment, the width d of each of the first and second portions P1 and P2 may be greatest at the same vertical level as the first surface 100a of the semiconductor substrate 100. The width d of each of the first and second portions P1 and P2 may be the smallest at the same vertical level as a bottom surface of the pixel isolation trench TR1. Widths of the third and fourth portions P3 and P4 in the first direction D1 may have the same value as the width d of the first and second portions P1 and P2 in the second direction D2. In an embodiment, the widths of the third and fourth portions P3 and P4 in the first direction D1 may be the greatest at the same vertical level as the first surface 100a of the semiconductor substrate 100. The widths of the third and fourth portions P3 and P4 may decrease as a distance to the second surface 100b decreases.

The width d of each of the first to fourth portions P1, P2, P3, and P4 in a direction of its short axis, a width of a pixel (e.g., a distance t between the first portion P1 and the second portion P2 in the second direction D2), and a length h of the pixel isolation structure 150 in the first direction D1 may be correlated with each other and may be restricted to be within specific numerical ranges.

For example, for an image sensor according to an embodiment of the present inventive concept, a G-factor defined by the following formula I may range from about 1200 to about 2200.

G=(h⁴/t³d²) [Formula 1]

where h is a length of the first portion in the first direction, t is a distance between the first and second portions in the second direction, and d is the largest width of the first portion in the second direction.

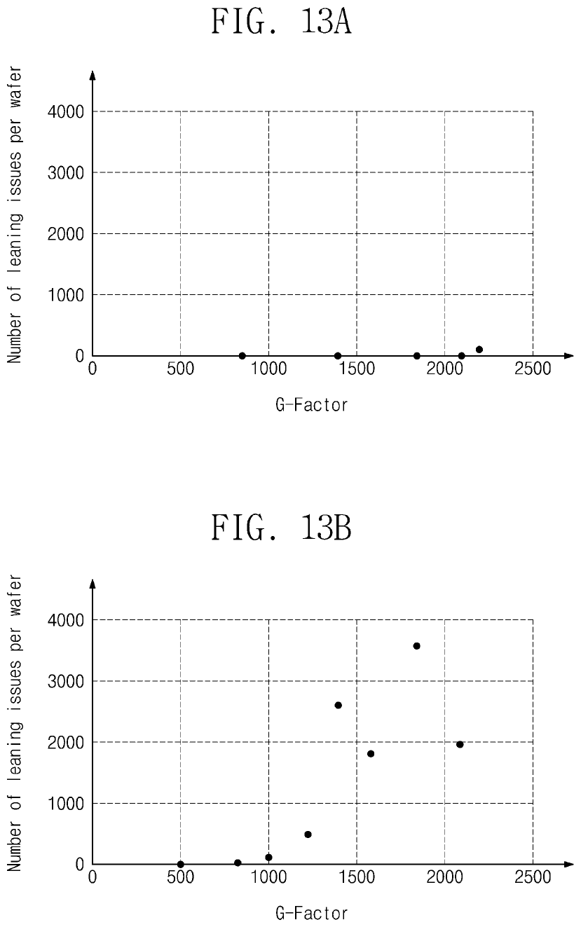

Since the image sensor has a G-factor ranging from about 1200 to about 2200, the image sensor may have a low failure rate, even when the image sensor has a high pixel density. In an embodiment in which an image sensor has a G-factor ranging from about 1200 to about 2200, it may be possible to cost-effectively fabricate a highly-reliable image sensor, even when the image sensor has a high pixel density. For example, in an embodiment in which the image sensor has a G-factor ranging from about 1200 to about 2200, it may be possible to reduce a leaning issue in a process of forming the pixel isolation structure 150. The reduction of the leaning issue according to the G-factor will be described in more detail with reference to FIGS. 13A to 13B, in conjunction with description of a method of fabricating an image sensor according to an embodiment of the present inventive concept.

The auxiliary isolation structure 160 may be disposed adjacent to the second surface 100b of the semiconductor substrate 100. The auxiliary isolation structure 160 may be vertically overlapped with the pixel isolation structure 150. The auxiliary isolation structure 160, along with the pixel isolation structure 150, may separate one of the pixel regions PR from the adjacent pixel regions PR. The auxiliary isolation structure 160 may be formed in an auxiliary trench T3, which is formed from the second surface 100b of the semiconductor substrate 100 towards the first surface 100a. In an embodiment, the auxiliary isolation structure 160 may be formed of or include at least one compound selected from, for example, silicon oxide, silicon nitride, and silicon oxynitride. A length of the auxiliary isolation structure 160 in the first direction D1 may be less than the length h of the pixel isolation structure 150 in the first direction D1. In an embodiment, a top surface of the auxiliary isolation structure 160 may be located between a bottom surface of the pixel isolation structure 150 and the second surface 100b of the semiconductor substrate 100 (e.g., in the first direction D1). However, embodiments of the present inventive concept are not necessarily limited thereto. For example, in an embodiment, the auxiliary isolation structure 160 may be extended toward the bottom surface of the pixel isolation structure 150 and may directly contact the bottom surface of the pixel isolation structure 150.

Referring back to FIGS. 3 and 4, the photoelectric conversion regions 110 may be provided in the pixel regions PR, respectively. For example, each pixel region PR may include one photoelectric conversion region 110. The photoelectric conversion regions 110 may be doped to have a conductivity type (e.g., a second conductivity type or an n type) that is different from that of the semiconductor substrate 100. The semiconductor substrate 100 and the photoelectric conversion region 110 may constitute a photodiode. For example, since the semiconductor substrate 100 and the photoelectric conversion region 110 have different conductivity types (e.g., the first and second conductivity types), the semiconductor substrate 100 and the photoelectric conversion region 110 may constitute a p-n junction and may serve as a photodiode. An level of the photocharges which are generated and accumulated in the photoelectric conversion region 110 of the photodiode may be proportional to an intensity of an incident light. In an embodiment, each of the photoelectric conversion regions 110 may include a first region adjacent to the first surface 100a and a second region adjacent to the second surface 100b. The first region and the second region may have different impurity concentrations from each other.

A device isolation insulating layer 103 may be disposed in each of the pixel regions PR and adjacent to the first surface 100a of the semiconductor substrate 100. The device isolation insulating layer 103 may be disposed in a device isolation trench TR2, which is formed by recessing the first surface 100a of the semiconductor substrate 100. The device isolation insulating layer 103 may have a decreasing width along a direction from the first surface 100a of the semiconductor substrate 100 towards the second surface 100b. A bottom surface of the device isolation insulating layer 103 may be vertically spaced apart from the photoelectric conversion regions 110. At least a portion of the device isolation insulating layer 103 may be overlapped with the pixel isolation structure 150 (e.g., in the first direction D1). For example, the pixel isolation structure 150 may be arranged to penetrate the device isolation insulating layer 103. A depth of the device isolation insulating layer 103 (e.g., length in the first direction D1) may be less than a depth of the pixel isolation structure 150. The device isolation insulating layer 103 may be formed of or include at least one of insulating materials. For example, the device isolation insulating layer 103 may include a liner oxide layer, which conformally covers a surface of the device isolation trench TR2, and a gapfill oxide layer, which fills a remaining portion of the device isolation trench TR2 covered with the liner nitride layer. The device isolation insulating layer 103 may be arranged to define first to third active patterns ACT1, ACT2, and ACT3 in the semiconductor substrate 100 and near the first surface 100a. The first to third active patterns ACT1, ACT2, and ACT3 may be disposed to be spaced apart from each other in each of the pixel regions PR and may have sizes different from each other.

The readout circuit layer 20 may be disposed on the first surface 100a of the semiconductor substrate 100 (e.g., directly thereon in the first direction D1). The readout circuit layer 20 may include readout circuits (e.g., MOS transistors), which are electrically connected to the photoelectric conversion regions 110. The readout circuit layer 20 may include the transfer transistor TX, the reset transistor RX, the selection transistor SX, and the drive transistor DX described with reference to an embodiment of FIG. 2.

The transfer transistor TX may be disposed on the first active pattern ACT1 of each of the pixel regions PR. The transfer transistor TX may include the transfer gate TG on the first active pattern ACT1 and the floating diffusion region FD. The transfer gate TG may include a lower portion, which is inserted into the semiconductor substrate 100, and an upper portion, which is connected to the lower portion and protrudes above the first surface 100a of the semiconductor substrate 100 (e.g., in the first direction D1). A gate dielectric layer G1 may be interposed between the transfer gate TG and the semiconductor substrate 100. The floating diffusion region FD may be disposed in a portion of the first active pattern ACT1 located at a side of the transfer gate TG. The floating diffusion region FD may have a second conductivity type (e.g., n-type), which is different from that of the semiconductor substrate 100.

The drive transistor DX and the selection transistor SX may be provided on the second active pattern ACT2. The drive transistor DX may include a drive gate SF, and the selection transistor SX may include a selection gate SG. The drive gate SF and the selection gate SG may be disposed on the second active pattern ACT2. The reset transistor RX may be disposed on the third active pattern ACT3. The reset transistor RX may include a reset gate RG on the third active pattern ACT3. A gate dielectric layer may be interposed between each of the drive, selection, and reset gates SF, SG, and RG and the semiconductor substrate 100.

The readout circuit layer 20 may include interlayer insulating layers 210 and interconnection structures. The interlayer insulating layers 210 may be disposed on the first surface 100a of the semiconductor substrate 100 to cover the transfer transistors TX and the logic transistors RX, SX, and DX described with reference to FIG. 2. For example, the interlayer insulating layers 210 may cover the transfer gates TG, the drive gates SF, the selection gates SG, and the reset gates RG. For example, in an embodiment, the interlayer insulating layers 210 may be formed of or include silicon oxide. In an embodiment, the interlayer insulating layers 210 may be composed of a single object. There may be no observable interface between the interlayer insulating layers 210.

The interconnection structures may be disposed in the interlayer insulating layers 210 and may be connected to the readout circuits. In an embodiment as shown in FIG. 4, the interconnection structures may include conductive lines 221 and contact plugs 222 connecting conductive lines 221 disposed on different levels to each other. The conductive lines 221 may be disposed in the interlayer insulating layers 210 and may be extended in the second and third directions D2 and D3. The contact plugs 222 may be located between the conductive lines 221, which are placed at various levels, and between the conductive lines 221 and the semiconductor substrate 100. The contact plugs 222 may connect the conductive lines 221 to the transfer transistors TX and the logic transistors RX, SX, and DX described with reference to FIG. 2. At least one of the contact plugs 222 may be disposed between the conductive lines 221 and the floating diffusion region FD.

The optically-transparent layer 30 may be disposed on the second surface 100b of the semiconductor substrate 100 (e.g., disposed directly thereon in the first direction D1). The optically-transparent layer 30 may be configured to allow a fraction of light, which is incident from the outside, to be focused on the photoelectric conversion layer 10. The optically-transparent layer 30 may include color filters 303 and micro lenses 307. The color filters 303 may be disposed on the pixel regions PR, respectively. The micro lenses 307 may be disposed on the color filters 303, respectively. The micro lenses 307 may have a convex shape capable of condensing light to be incident into the pixel regions PR. When viewed in a plan view, the micro lenses 307 may be overlapped with the photoelectric conversion regions 110, respectively (e.g., in the first direction D1).

An anti-reflection layer 132 and an interface insulating layer 134 may be disposed between the second surface 100b of the semiconductor substrate 100 and the color filters 303. The anti-reflection layer 132 may be configured to prevent light, which is incident into the second surface 100b of the semiconductor substrate 100, from being reflected, and this may allow the incident light to be effectively incident into the photoelectric conversion layer 10. A lattice structure 320 may be disposed between the anti-reflection layer 132 and the interface insulating layer 134. The lattice structure 320 may include an insulating pattern and a conductive pattern on the insulating pattern. A planarization layer 305 may be arranged between the color filters 303 and the micro lenses 307.

The color filters 303 may include primary color filters. For example, the color filters 303 may include green, red, and blue filters. The color filters 303 may be arranged in a Bayer pattern. In an embodiment, the color filters 303 may include color filters of other colors (e.g., cyan, magenta, or yellow).

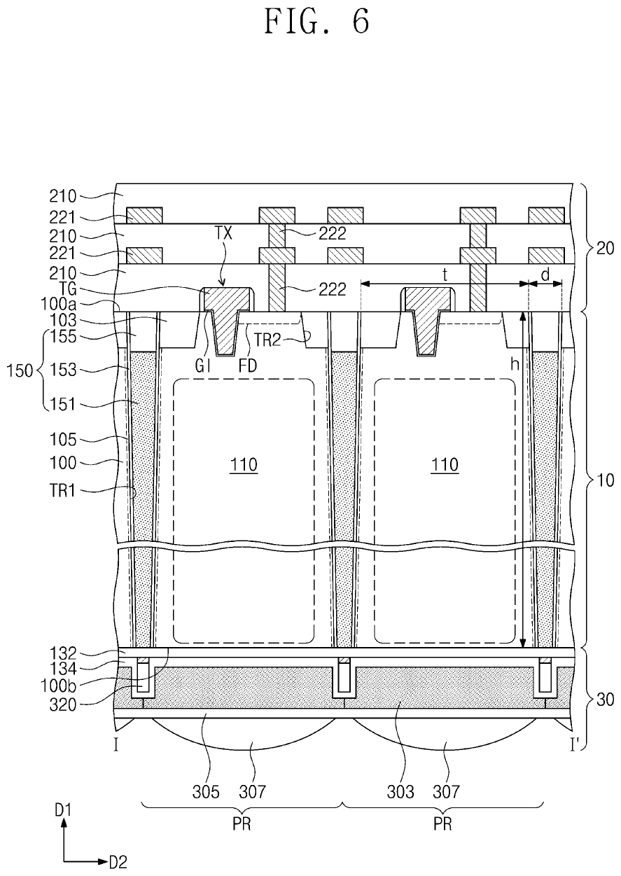

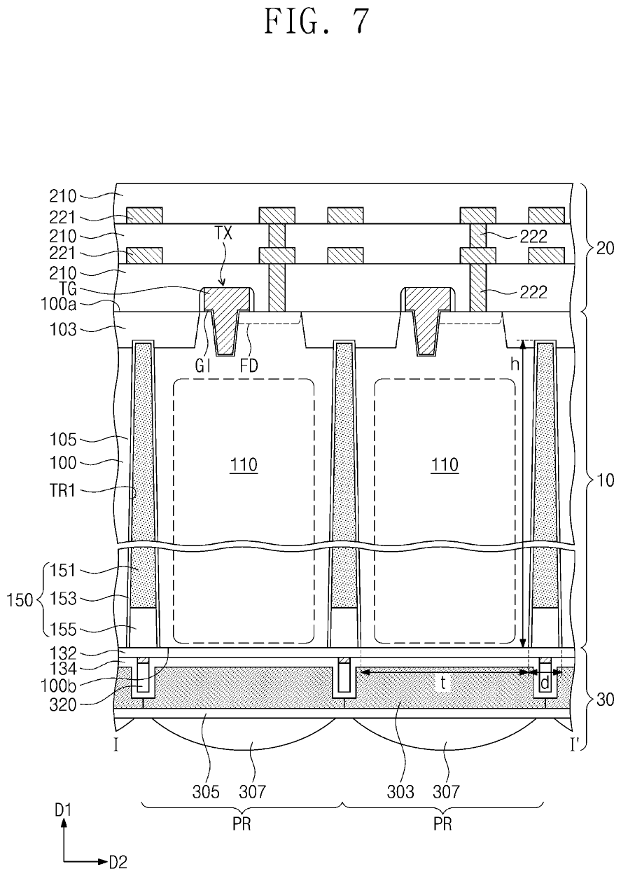

FIGS. 6 and 7 are cross-sectional views illustrating an image sensor according to an embodiment of the present inventive concept. For concise description, a previously described element may be identified by the same reference number without repeating an overlapping description thereof.

Referring to FIG. 6, an image sensor according to an embodiment of the present inventive concept may not include the auxiliary isolation structure 160 of FIG. 4. The pixel isolation structure 150 may be extended from the first surface 100a of the semiconductor substrate 100 to the second surface 100b. An upper portion of the pixel isolation structure 150 may directly contact the first surface 100a of the semiconductor substrate 100 and the lower portion of the pixel isolation structure 150 may directly contact the second surface 100b of the semiconductor substrate 100. The pixel isolation structure 150 may be arranged to penetrate the semiconductor substrate 100. For example, a depth h of the pixel isolation structure 150 may be substantially equal to a vertical thickness of the semiconductor substrate 100. A bottom of the pixel isolation trench TR1 may be defined by the anti-reflection layer 132. A bottom end of the pixel isolation structure 150 filling the pixel isolation trench TR1 may directly contact the anti-reflection layer 132. A bottom end of the insulating pattern 153 and a bottom end of the conductive pattern 151 may be coplanar with the second surface 100b of the semiconductor substrate 100 (e.g., in the first direction D1). A width of the pixel isolation structure 150 may gradually decrease along a direction from the first surface 100a towards the second surface 100b.

Referring to FIG. 7, the pixel isolation structure 150 may have a first width near the first surface 100a of the semiconductor substrate 100 and a second width, which is larger than the first width, near the second surface 100b of the semiconductor substrate 100. A width of the pixel isolation structure 150 may gradually increase along a direction from the first surface 100a towards the second surface 100b.

The pixel isolation structure 150 may include the insulating pattern 153, the conductive pattern 151, and the capping pattern 155, as described above. The pixel isolation structure 150 may be in direct contact with the device isolation insulating layer 103. For example, a portion of the insulating pattern 153 of the pixel isolation structure 150 may be in direct contact with the device isolation insulating layer 103. The portion of the insulating pattern 153 may be disposed between the device isolation insulating layer 103 and the conductive pattern 151. The uppermost surface of the pixel isolation structure 150 may be positioned at a level below the first surface 100a of the semiconductor substrate 100.

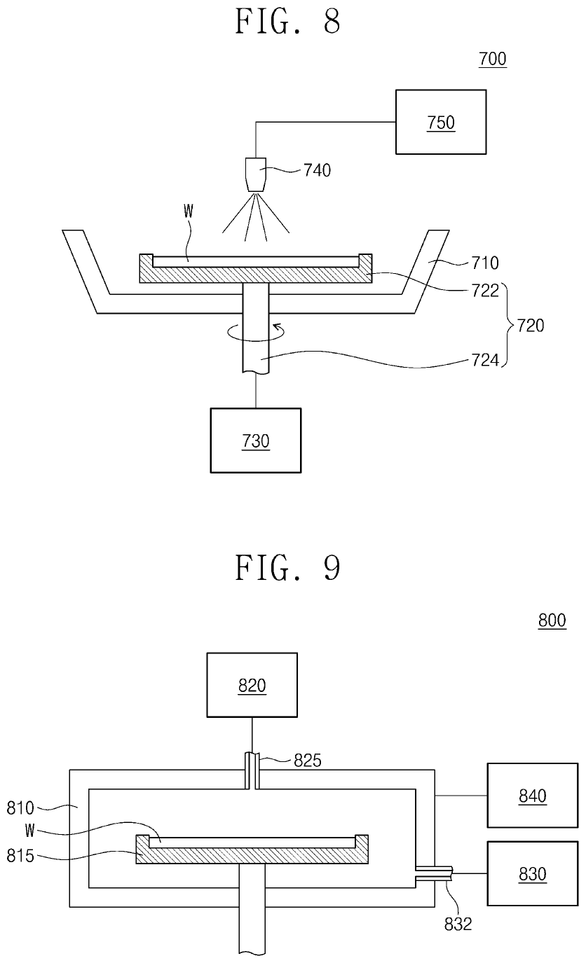

FIG. 8 is a diagram schematically illustrating a wet treatment system which is used in a process of fabricating an image sensor according to an embodiment of the present inventive concept. FIG. 9 is a diagram schematically illustrating a drying system which is used in the process of fabricating an image sensor according to an embodiment of the present inventive concept. Prior to describing a method of fabricating an image sensor, a wet treatment system and a drying system, which may be used in the fabrication method, will be described in more detail below.

Referring to FIG. 8, a wet treatment system 700 may include a container 710, a supporting member 720, a driving part 730, a spray nozzle 740, and a treatment solution supplying part 750. The container 710 may have a top-opened bowl-shaped structure. The container 710 may be configured to contain a treatment solution which is used in a wet treatment process.

The supporting member 720 may include a spin chuck 722, which supports a wafer W during the wet treatment process, and a shaft 724, which connects the spin chuck 722 to the driving part 730. The spin chuck 722 may be configured to be movable in upward and downward directions for operations of loading and unloading the wafer W. The shaft 724 may be arranged to penetrate a bottom of the container 710 and may be connected to the driving part 730. The spin chuck 722 may be rotated by a force that is exerted from the driving part 730 through the shaft 724. For example, the driving part 730 may include a motor.

The spray nozzle 740 may be positioned over the wafer W and may be configured to supply the treatment solution onto the wafer W. The treatment solution supplying part 750 may supply the treatment solution to the spray nozzle 740, during the wet treatment process. In an embodiment, the treatment solution supplying part 750 may be configured to contain various kinds of treatment solutions, which will be used in wet treatment processes on the wafer W, and to supply a treatment solution, which is suitable for each process, to the spray nozzle 740.

Referring to FIG. 9, a drying system 800 may include a drying chamber 810, a wafer chuck 815, a fluid supplying part 820, a fluid inlet port 825, a pressure control unit 830, an exhausting part 832, and a temperature control unit 840. The drying chamber 810 may be hermetically sealed during a drying process.

The wafer chuck 815 may be used to support the wafer W, during the drying process. The wafer chuck 815 may be configured to be movable in upward and downward directions for the operations of loading and unloading the wafer W.

The fluid supplying part 820 may be configured to store a treatment fluid which will be used in the drying process. The fluid supplying part 820 may also be configured to supply the treatment fluid into the drying chamber 810 through the fluid inlet port 825, which is arranged to pass through a top cover of the drying chamber 810.

The pressure control unit 830 and the temperature control unit 840 may be connected to the drying chamber 810. The pressure control unit 830 may be configured to control an internal pressure of the drying chamber 810, during the drying process. The pressure control unit 830 may be connected to the exhausting part 832. For example,- in an embodiment, the pressure control unit 830 may include a pump. The temperature control unit 840 may also be configured to control an internal temperature of the drying chamber 810, during the drying process. For example, the temperature control unit 840 may include temperature control jackets, which are disposed adjacent to sidewalls of the drying chamber 810.

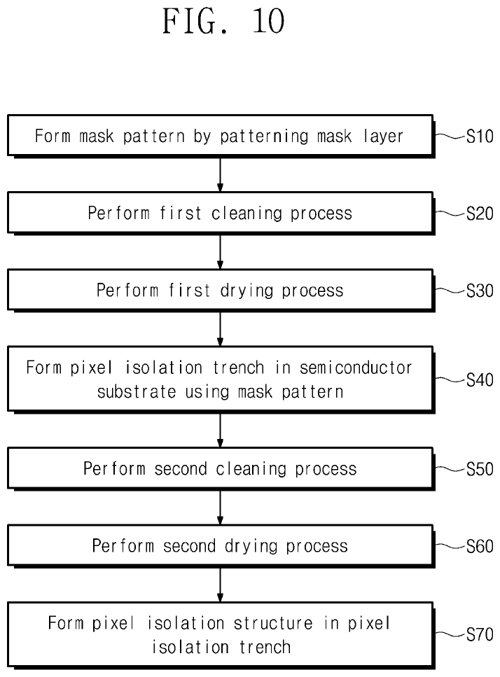

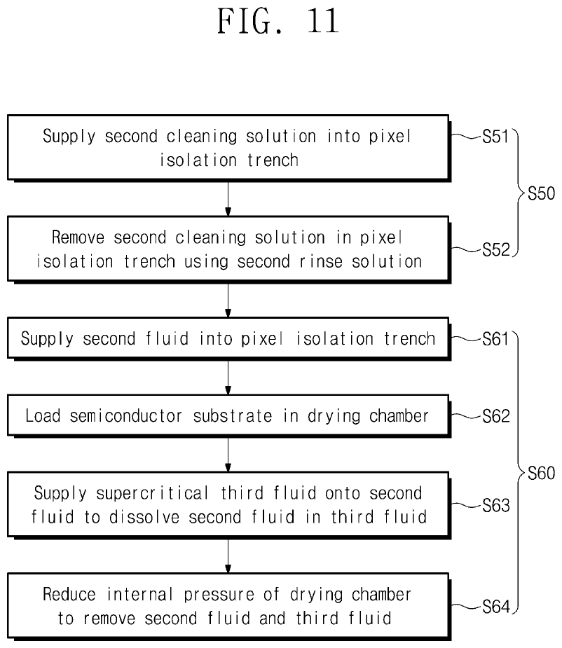

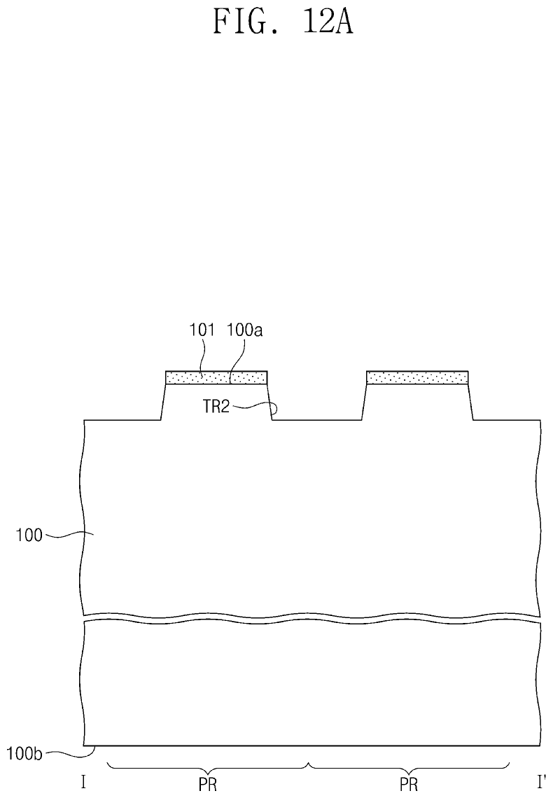

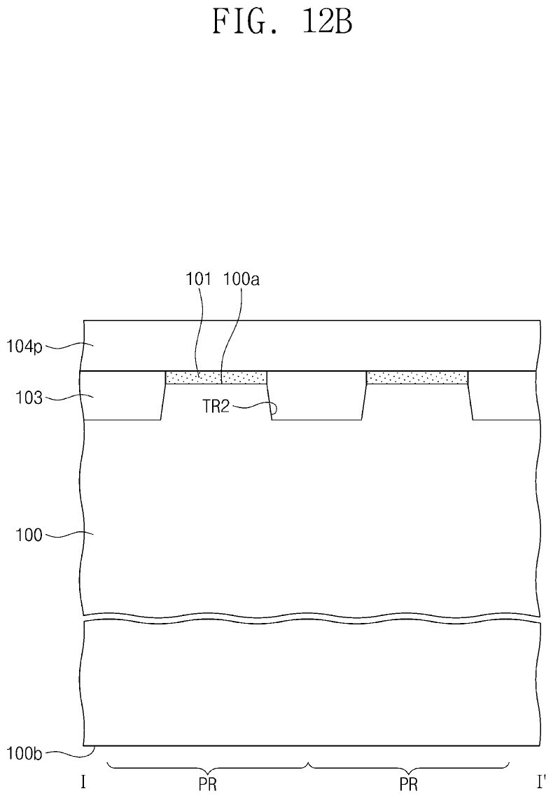

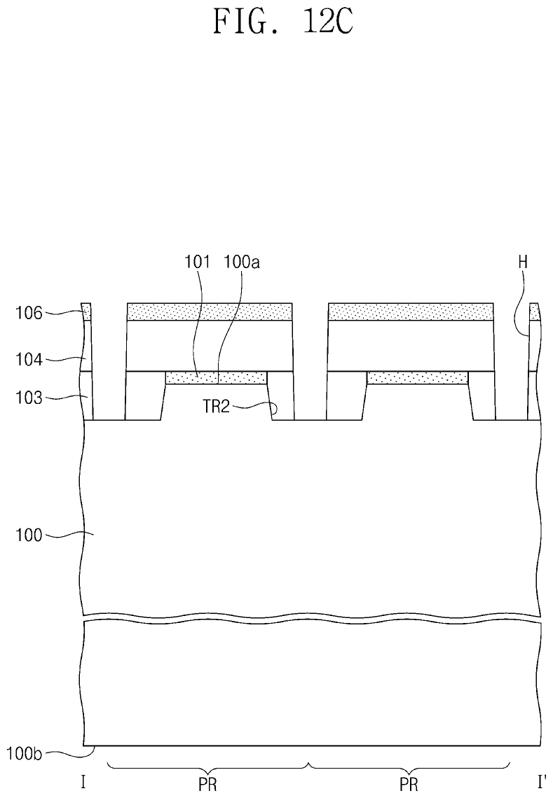

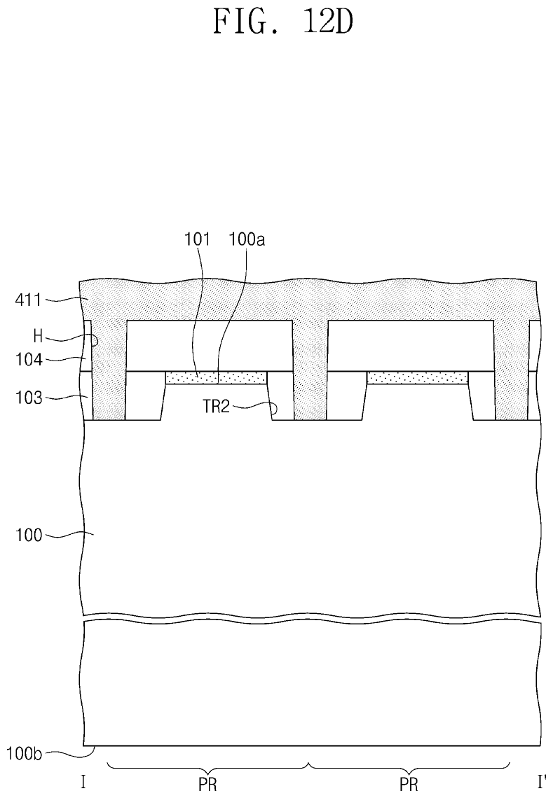

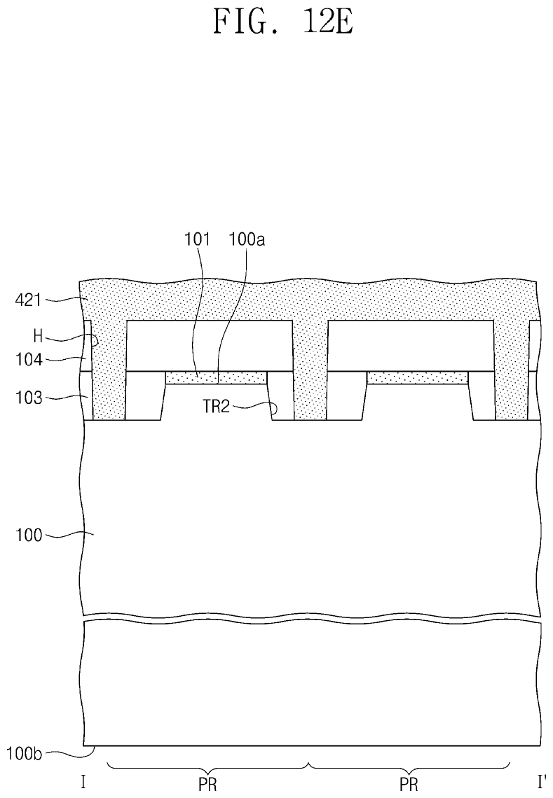

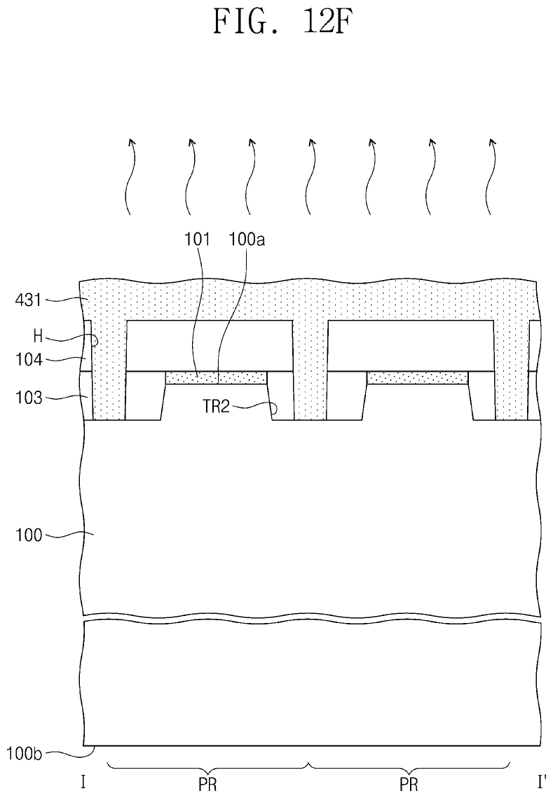

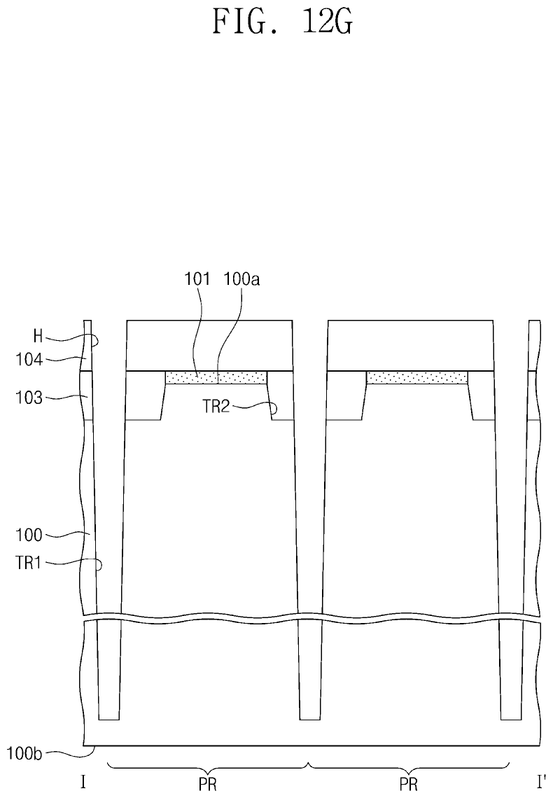

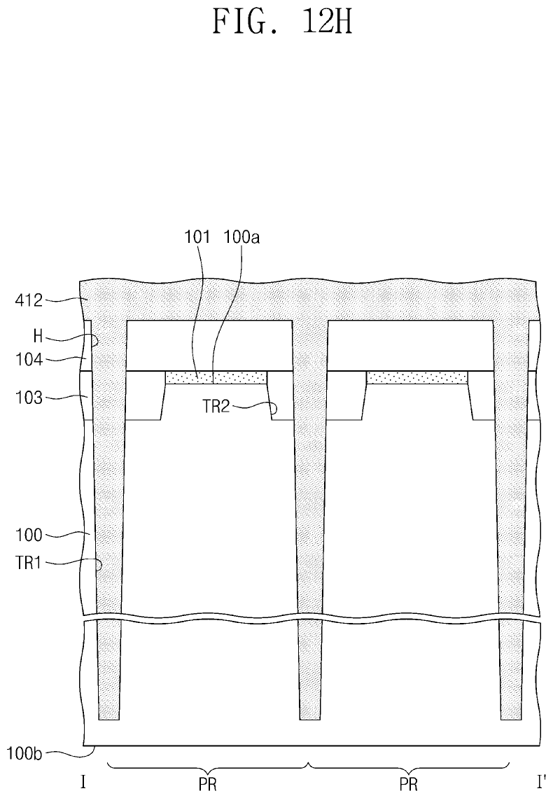

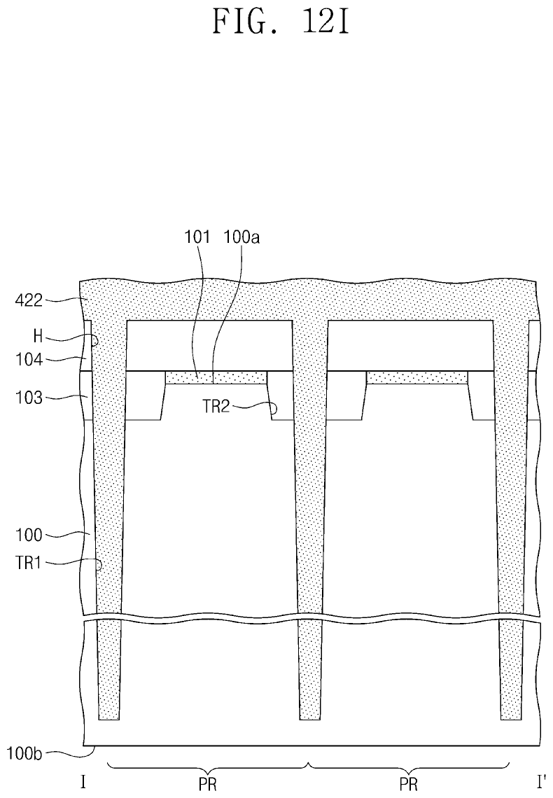

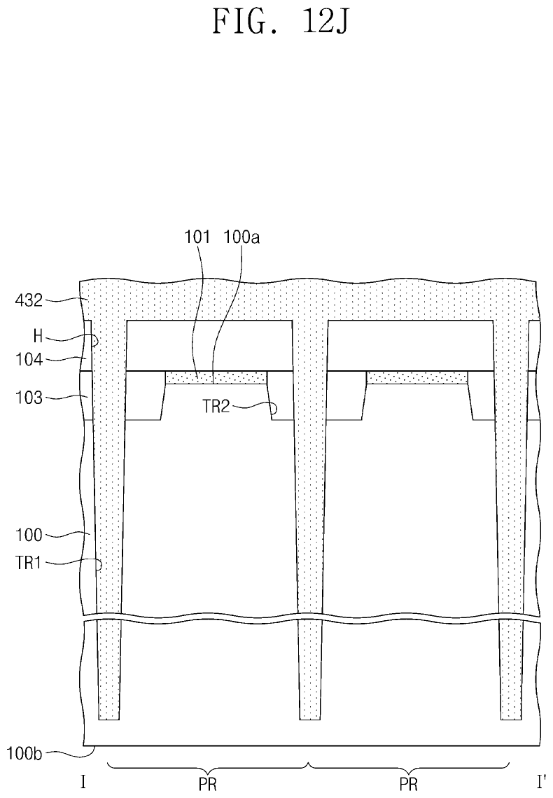

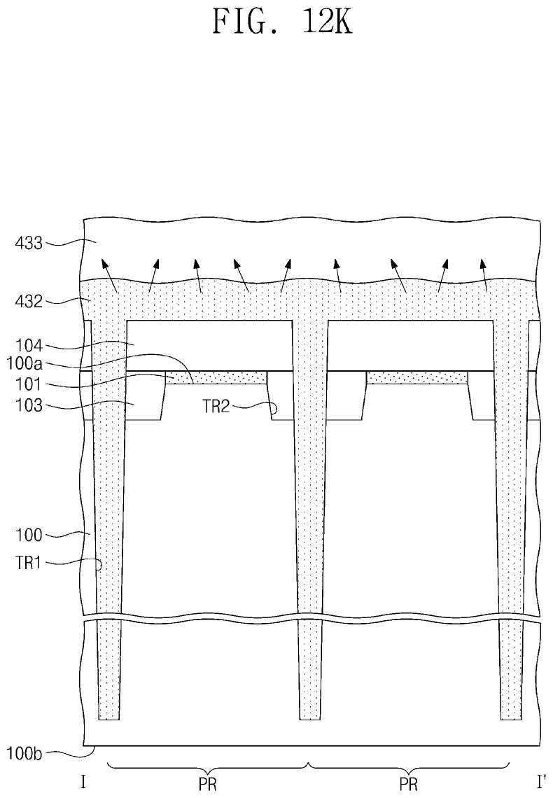

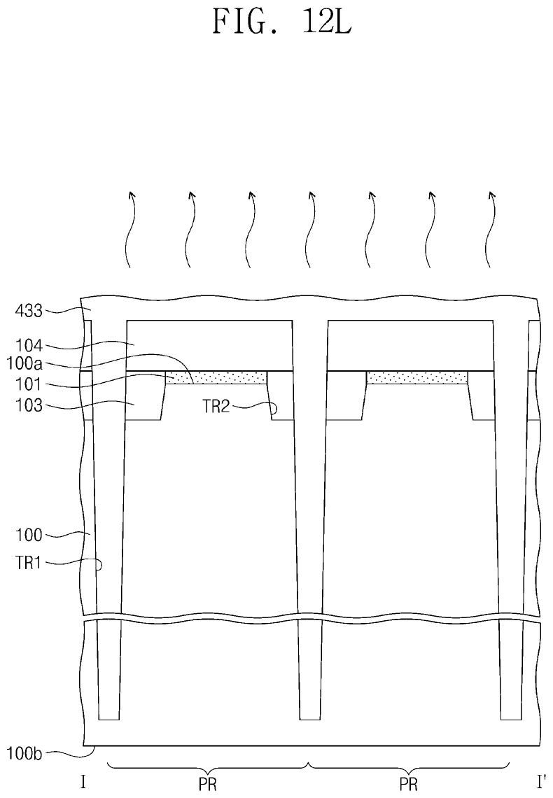

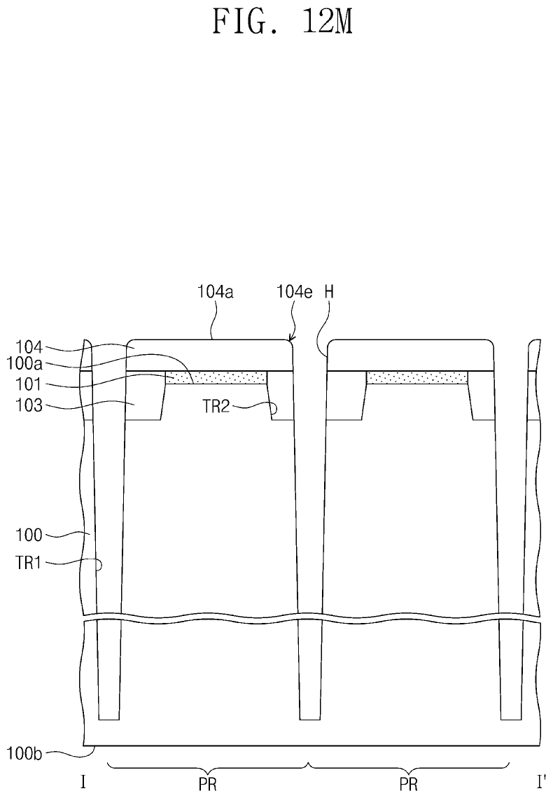

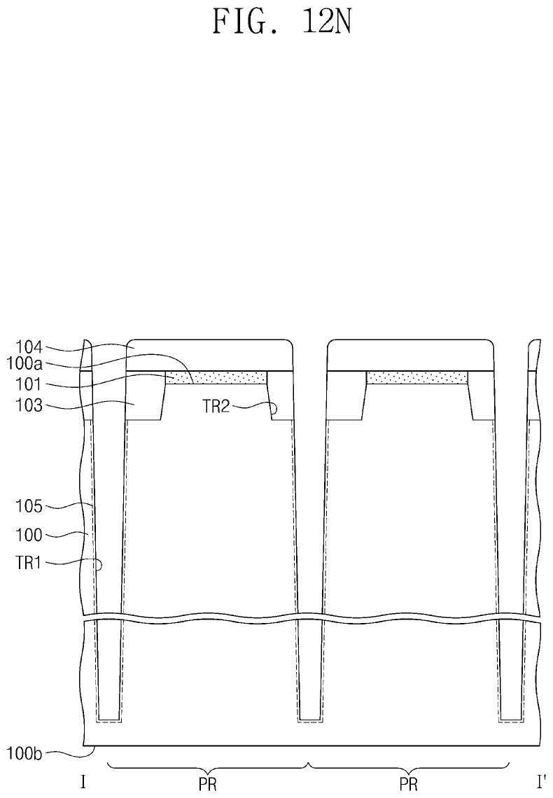

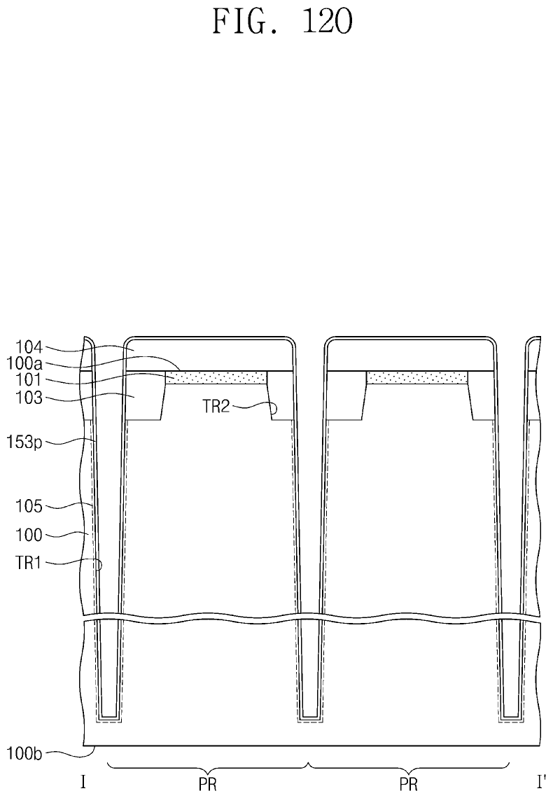

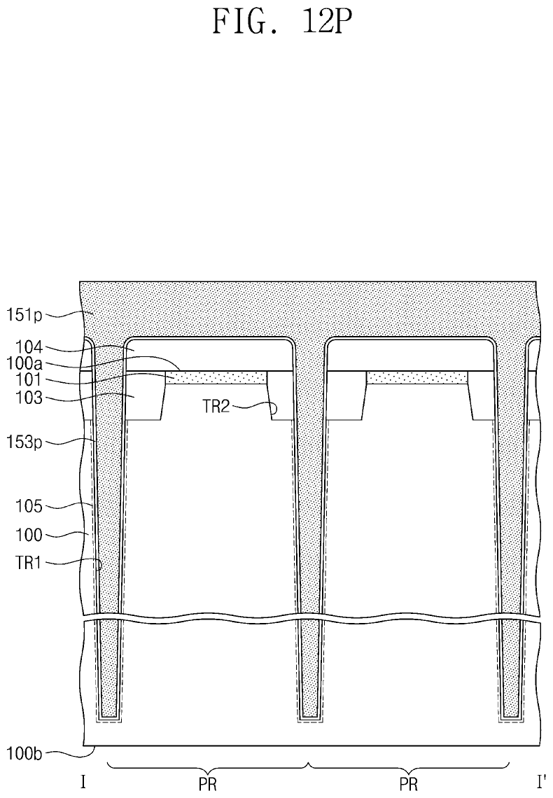

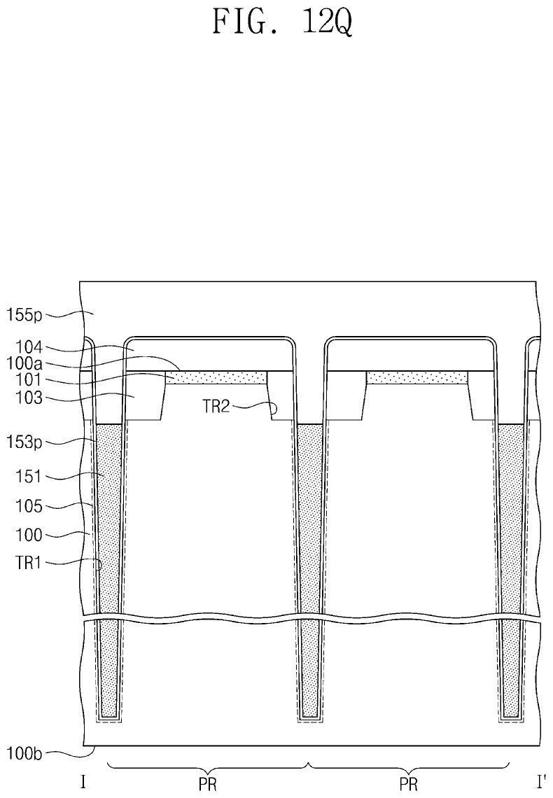

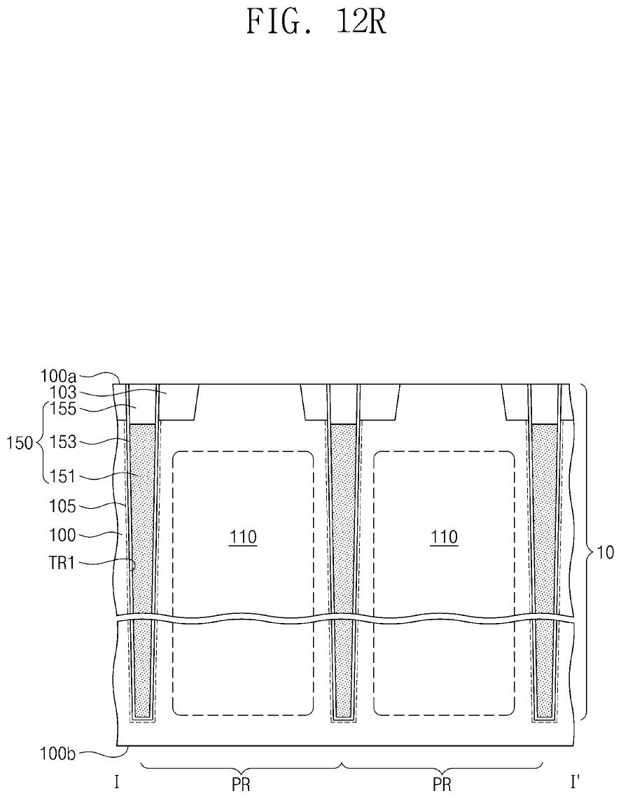

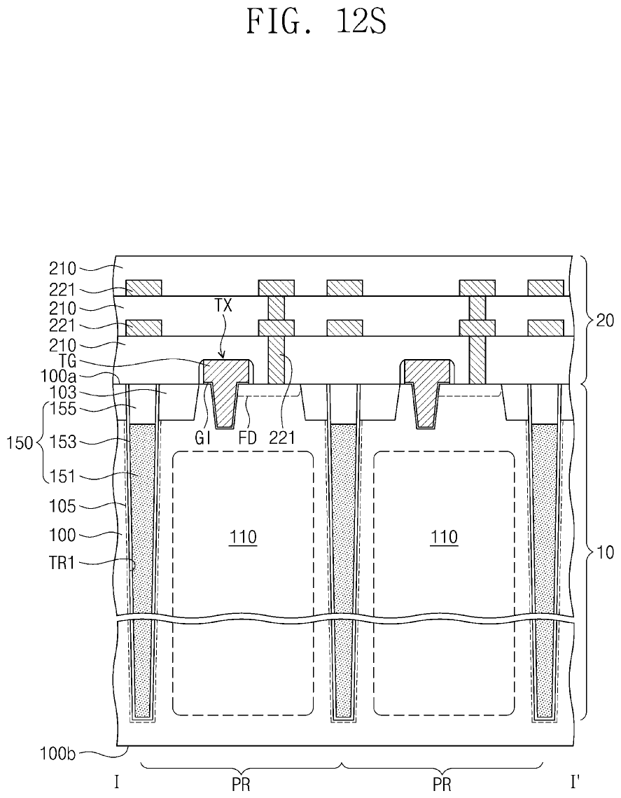

FIG. 10 is a flow chart illustrating a method of forming a pixel isolation structure, according to an embodiment of the present inventive concept. FIG. 11 is a flow chart illustrating a second cleaning process and a second drying process, according to an embodiment of the present inventive concept. FIGS. 12A to 12S are cross-sectional views illustrating a method of fabricating an image sensor, according to embodiments of the present inventive concept.

Referring to FIG. 12A, the semiconductor substrate 100 of a first conductivity type (e.g., p-type) may be provided. The semiconductor substrate 100 may have the first surface 100a and the second surface 100b that are opposite to each other. For example, the first surface 100a may be an upper surface of the semiconductor substrate 100 and the second surface 100b may be a lower surface of the semiconductor substrate 100. The semiconductor substrate 100 may include a bulk silicon substrate of a first conductivity type and an epitaxial layer, which is formed on the bulk silicon substrate and is of the first conductivity type. In an embodiment, the epitaxial layer may be formed by a selective epitaxial growth (SEG) process using the bulk silicon substrate as a seed, and the epitaxial layer may be doped with impurities of the first conductivity type, during the epitaxial growth process. For example, the epitaxial layer may contain p-type impurities.

A device isolation trench TR2 may be formed by patterning the first surface 100a of the semiconductor substrate 100. The first to third active regions ACT1, ACT2, and ACT3 described with reference to an embodiment of FIG. 3 may be defined in the pixel regions PR of each of the device isolation trench TR2. The formation of the device isolation trench TR2 may include forming a sacrificial pattern 101 on the first surface 100a of the semiconductor substrate 100 and anisotropically etching the semiconductor substrate 100 using the sacrificial pattern 101 as an etch mask. In an embodiment, the sacrificial pattern 101 may be formed of or include at least one compound selected from silicon nitride and silicon oxynitride.

Referring to FIG. 12B, the device isolation insulating layer 103 may be formed to fill the device isolation trench TR2. The formation of the device isolation insulating layer 103 may include thickly depositing an insulating material on the semiconductor substrate 100 with the device isolation trench TR2 and performing a planarization process on the insulating material. The planarization process on the insulating material may be performed such that a top surface of the insulating material is located at the same level as a top surface of the sacrificial pattern 101.

A mask layer 104p may then be formed on the first surface 100a of the semiconductor substrate 100. In an embodiment, the mask layer 104p may include a spin-on-hardmask (SOH) material. For example, the mask layer 104p may be formed of or include a carbon-containing material.

Referring to FIGS. 10, 12B, and 12C, a mask pattern 104 may be formed by patterning the mask layer 104p in block S10. The mask pattern 104 may have at least one opening H, which is formed to vertically penetrate the mask pattern 104. In an embodiment, the formation of the mask pattern 104 may include forming a photoresist 106 on the mask layer 104p and performing an anisotropic etching process using the photoresist 106 as an etch mask. The device isolation insulating layer 103 may also be etched during the etching process to expose a bottom surface of the device isolation trench TR2. The photoresist 106 may be removed after the formation of the mask pattern 104.

Referring to FIGS. 8, 10, and 12D, a first cleaning process may be performed on the semiconductor substrate 100 in block S20. In an embodiment, the first cleaning process may include a spin-on-process, which is performed using the wet treatment system 700 described with reference to FIG. 8. For example, the first cleaning process may include loading the semiconductor substrate 100 on the spin chuck 722 and supplying a first cleaning solution 411 onto the semiconductor substrate 100. The spin chuck 722 may be rotated while the first cleaning solution 411 is supplied onto the semiconductor substrate 100. The first cleaning solution 411 may be supplied to fill the opening H of the mask pattern 104 and to remove an etch residue that is produced in the etching process. In an embodiment, the first cleaning solution 411 may include at least one compound selected from ozone, hydrogen peroxide, phosphoric acid, and hydrofluoric acid.

Referring to FIGS. 8, 12D, and 12E, a first rinse process may be performed to remove at least a portion of the first cleaning solution 411. In an embodiment, the first rinse process may include a spin-on-process, which is performed using the wet treatment system 700. For example, the first rinse process may include supplying a first rinse solution 421 onto the first cleaning solution 411 while rotating the spin chuck 722. The first cleaning solution 411 may be removed by the rotation of the spin chuck 722. A space in the opening H, from which the first cleaning solution 411 is removed, may be filled with the first rinse solution 421. In an embodiment, the process of supplying the first rinse solution 421 and rotating the spin chuck 722 may be continuously performed until the first cleaning solution 411 left on (e.g., remaining on) the semiconductor substrate 100 is diluted to a concentration of less than or equal to about 2 wt %. In an embodiment, the first rinse solution 421 may include, for example, deionized water (DIW).

Referring, to FIGS. 8, 10, and 12F, a first drying process may be performed on the semiconductor substrate 100 in block S30. In an embodiment, the first drying process may include supplying a first fluid 431 into the opening H and drying the first fluid 431. The first drying process may include a spin-on-process, which is performed using the wet treatment system 700. For example, the spin chuck 722 may be rotated to at least partially remove the first cleaning solution 411 and the first rinse solution 421, which are left on the semiconductor substrate 100. Thereafter, the first fluid 431 may be supplied onto the semiconductor substrate 100 while rotating the spin chuck 722. In an embodiment, the first fluid 431 may include, for example, isopropyl alcohol. The semiconductor substrate 100 may then be dried by vaporizing the first fluid 431 to remove the first fluid 431 on the semiconductor substrate 100. The first fluid 431 may have a surface tension that is lower than the surface tension of the first rinse solution 421. In an embodiment, in the first drying process, a temperature of the first fluid 431 may be increased to lower the surface tension of the first fluid 431. The first fluid 431 may have a temperature higher than the temperature of the first rinse solution 421. For example, in an embodiment, the temperature of the first fluid 431, which is supplied onto the semiconductor substrate 100, may be in a range from about 60° C. to about 80° C.

Referring to FIGS. 10 and 12G, the pixel isolation trench TR1 may be formed in the semiconductor substrate 100 using the mask pattern 104 in block S40. The pixel isolation trench TR1 may be formed by patterning the device isolation insulating layer 103 and the first surface 100a of the semiconductor substrate 100. The formation of the pixel isolation trench TR1 may include anisotropically etching the semiconductor substrate 100 using the mask pattern 104 as an etch mask.

The pixel isolation trench TR1 may be formed in the semiconductor substrate 100 to vertically extend from the first surface 100a towards the second surface 100b and to expose a portion of a side surface of the semiconductor substrate 100. The pixel isolation trench TR1 may be formed to be deeper than the device isolation trench TR2 and to penetrate a portion of the device isolation trench TR2. Even when the pixel isolation trench TR1 is formed by an anisotropic etching process, the pixel isolation trench TR1 may be formed to have a gradually decreasing width along a direction from the first surface 100a towards the second surface 100b. For example, the pixel isolation trench TR1 may have inclined lateral side surfaces (e.g., sidewalls). In an embodiment, a bottom surface of the pixel isolation trench TR1 may be spaced apart from the second surface 100b of the semiconductor substrate 100. The pixel isolation trench TR1 may be formed to have a depth, a width, and a distance, which allow the G-factor (G) in the formula 1 to have a value in a range of about 1200 to about 2200. In an embodiment in which the G-factor (G) has a value of less than or equal to 2200, it may be possible to prevent a leaning issue of the semiconductor substrate 100 from occurring in a second drying process to be described below.

Referring to FIGS. 8, 10, 11, and 12H, a second cleaning process may be performed on the semiconductor substrate 100 in block S50. In an embodiment, the second cleaning process may include a spin-on-process, which is performed using the wet treatment system 700. For example, the second cleaning process may include loading the semiconductor substrate 100 on the spin chuck 722 and supplying a second cleaning solution 412 onto the semiconductor substrate 100 in block S51. The spin chuck 722 may be rotated while the second cleaning solution 412 is supplied onto the semiconductor substrate 100. The second cleaning solution 412 may be supplied to fill the pixel isolation trench TR1 and to remove an etch residue, which is produced in an etching process for forming the pixel isolation trench TR1. In an embodiment, the second cleaning solution 412 may include at least one compound selected from ozone (O₃), hydrogen peroxide (H₂O₂), phosphoric acid, and hydrofluoric acid.

Referring to FIGS. 8, 10, 11, 12H, and 12I, a second rinse process may be performed to remove at least a portion of the second cleaning solution 412. The second rinse process may include a spin-on-process, which is performed using the wet treatment system 700. For example, the second rinse process may include supplying a second rinse solution 422 onto the second cleaning solution 412 while rotating the spin chuck 722. The second cleaning solution 412 may be removed by the rotation of the spin chuck 722. A space in the pixel isolation trench TR1, from which the second cleaning solution 412 is removed, may be filled with the second rinse solution 422. In an embodiment, the process of supplying the second rinse solution 422 and rotating the spin chuck 722 may be continuously performed until the second cleaning solution 412 left on the semiconductor substrate 100 is diluted to a concentration that is less than or equal to about 2 wt %. In an embodiment, the second rinse solution 422 may include, for example, deionized water.

Referring to FIGS. 8 to 11 and 12I to 12L, a second drying process may be performed on the semiconductor substrate 100 in block S60. In an embodiment, the second drying process in block S60 may include supplying a second fluid 432 into the pixel isolation trench TR1 in block S61, loading the semiconductor substrate 100 in the drying chamber 810 in block S62, supplying a third fluid 433 in a supercritical state onto the second fluid 432 to dissolve the second fluid 432 in the third fluid 433 in block S63, reducing an internal pressure of the drying chamber 810 to remove the second fluid 432 and the third fluid 433 in block S64.

For example, referring to FIGS. 8, 11, 12I, and 12J, the second fluid 432 may be supplied into the pixel isolation trench TR1 in block S61. For example, the spin chuck 722 may be rotated to at least partially remove the second rinse solution 422 left on the semiconductor substrate 100. Thereafter, the second fluid 432 may be supplied onto the semiconductor substrate 100 while rotating the spin chuck 722. The second fluid 432 may fill an inner space of the pixel isolation trench TR1. In an embodiment, the second fluid 432 may be formed of or include the same material as the first fluid 431 described with reference to FIG. 12F. For example, in an embodiment, the second fluid 432 may be formed of or include isopropyl alcohol.

In an embodiment, before the supplying of the second fluid 432, a temperature of the second fluid 432 may be increased to lower the surface tension of the first fluid 431. However, embodiments of the present inventive concept are not necessarily limited thereto. For example, in an embodiment, a process of increasing the temperature of the second fluid 432 may be omitted, and the second fluid 432 may have a lower temperature than the first fluid 431, when it is supplied onto the semiconductor substrate 100.

Referring to FIGS. 9, 11, 12I, and 12J, the semiconductor substrate 100 may be loaded in the drying chamber 810 in block S62. The semiconductor substrate 100 may be provided on the wafer chuck 815. The semiconductor substrate 100 may be a portion of the wafer W. The wafer chuck 815 may not be rotated during the second drying process to be described below.

Referring to FIGS. 9, 11, and 12K, the third fluid 433 in the supercritical state may be supplied onto the second fluid 432. In this embodiment, the second fluid 432 may be dissolved in the third fluid 433 in block S63. The third fluid 433 may have a surface tension that is lower than the surface tension of the second fluid 432. In addition, the third fluid 433 may have a surface tension that is lower than the surface tension of the first fluid 431 described with reference to FIG. 12F. A supercritical fluid has continuously-varying physical properties (e.g., density, viscosity, diffusion coefficient, and polarity) from a gas-like state to a liquid-like state, depending on a change in its pressure and temperature. The third fluid 433 in the supercritical state may have high dissolution ability, high diffusion coefficient, low viscosity, and low surface tension. For example, the third fluid 433 in the supercritical state may have a surface tension that is close to zero. In an embodiment, the third fluid 433 may include carbon dioxide.

Prior to the supplying of the third fluid 433, an internal space of the drying chamber 810 may be controlled to be in a first process condition. The first process condition may be chosen to allow the third fluid 433 to be in its supercritical state, and under the first process condition, the internal space of the drying chamber 810 may have high temperature and high pressure. For example, under the first process condition, the internal space of the drying chamber 810 may have pressure in a range from about 10 atm to about 200 atm and temperature in a range from about 100° C. to about 250° C. Since the internal space of the drying chamber 810 is controlled to be in the first process condition, an internal pressure of the drying chamber 810 may be gradually increased from atmospheric pressure to a pressure in a range of about 10 to about 200 atm. An internal temperature of the drying chamber 810 may be gradually increased from the room temperature to temperature in a range of about 100° C. to about 250° C. In an embodiment, the vaporizing of the third fluid 433 may be performed under a pressure that is higher than the pressure for the vaporizing of the first fluid 431.

The third fluid 433 may be supplied into the drying chamber 810 while the internal space of the drying chamber 810 is maintained to the first process condition. In an embodiment, the third fluid 433 may be supplied onto the second fluid 432 through the fluid inlet port 825 from the fluid supplying part 820. The second fluid 432 may be dissolved in the third fluid 433 to replace at least a portion of the second fluid 432 with the third fluid 433. The third fluid 433 may be diffused into the pixel isolation trench TR1, and at least a portion of the second fluid 432 in the pixel isolation trench TR1 may be replaced with the third fluid 433.

Referring to FIGS. 9, 11, 12K, and 12L, the second fluid 432 and the third fluid 433 may be removed by lowering an internal pressure of the drying chamber 810 in block S64. In an embodiment, the internal space of the drying chamber 810 may be controlled to be in a second process condition, before the removing of the second fluid 432 and the third fluid 433. The second process condition may be chosen to allow the third fluid 433 to be in its gaseous state, and the pressure and temperature in the second process condition may be lower than those in the first process condition. For example, the internal pressure of the drying chamber 810 may be lowered from a pressure in a range of about 10 atm to about 200 atm to the atmospheric pressure. The internal temperature of the drying chamber 810 may also be lowered from a temperature in a range of about 100° C. to about 250° C. to a temperature less than or equal to about 100° C. For example, the third fluid 433 may be in a gaseous state, when the pressure and temperature are lower than about 31° C. and about 73 atm. The second fluid 432, along with the third fluid 433, may be vaporized and may be exhausted to the outside of the drying chamber 810 through the exhausting part 832.

In an embodiment, the internal space of the drying chamber 810 may be repeatedly controlled to be in the first process condition and the second process condition.

In an embodiment, the step of supplying the third fluid 433 onto the second fluid 432 and the step of controlling an internal condition of the chamber to exhaust the second fluid 432 and the third fluid 433 may be repeatedly performed until the internal space of the pixel isolation trench TR1 is completely dried.

Since the drying process is performed on the pixel isolation trench TR1 provided with fluid with low surface tension, it may be possible to prevent the pixel isolation trench TR1 from being deformed or to prevent a portion of the semiconductor substrate 100, which is located between the pixel isolation trenches TR1, from being collapsed.

Referring to FIG. 12M, an isotropic etching process may be performed on the mask pattern 104 to increase an upper width of the opening H. A level of a top surface 104a of the mask pattern 104 may be lowered as the isotropic etching process is performed. A corner portion 104e of a top end of the opening H may be etched to have a rounded shape.

In an embodiment, a third cleaning process and a third drying process may be further performed, after the isotropic etching process on the mask pattern 104. The third cleaning process and the third drying process may be performed in a manner that is similar to the second cleaning process and the second drying process described with reference to embodiments of FIGS. 8 to 11 and 12G to 12L.

For example, a third cleaning solution may be supplied onto the semiconductor substrate 100 to remove etch residues which are produced during the isotropic etching process on the mask pattern 104. A third rinse solution may be supplied onto the semiconductor substrate 100 to at least partially remove the third cleaning solution. A fourth fluid may be supplied onto the semiconductor substrate 100, and then, the semiconductor substrate 100 may be transferred into the drying chamber 810. A fifth fluid in a supercritical state may then be supplied onto the fourth fluid, and then, the fourth fluid, along with the fifth fluid, may be removed. In an embodiment, the third cleaning solution, the third rinse solution, the fourth fluid, and the fifth fluid may be the same as the second cleaning solution 412, the second rinse solution 422, the second fluid 432, and the third fluid 433, respectively, described with reference to embodiments of FIGS. 12H to 12L. Process steps, which are similar to those in the previously-described embodiment, may not be described in much further detail for economy of description.

Referring to FIG. 12N, an ion implantation process may be performed to form a barrier region 105 in the semiconductor substrate 100. The barrier region 105 may contain impurities that are of the same conductivity type (e.g., the first conductivity type or the p-type) as the semiconductor substrate 100. A doping concentration of the barrier region 105 may be hider than the doping concentration in the semiconductor substrate 100.

In an embodiment, a fourth cleaning process and a fourth drying process may be performed, after the ion implantation process on the semiconductor substrate 100. The fourth cleaning process and the fourth drying process may be performed in a manner that is similar to the second cleaning process and the second drying process described with reference to embodiments of FIGS. 8 to 11 and 12G to 12L.

For example, a fourth cleaning solution may be supplied onto the semiconductor substrate 100 to remove etch residues, which are produced during the ion implantation process on the semiconductor substrate 100. A fourth rinse solution may be supplied onto the semiconductor substrate 100 to at least partially remove the fourth cleaning solution. A sixth fluid may be supplied onto the semiconductor substrate 100, and the semiconductor substrate 100 may be transferred into the drying chamber. Thereafter, a seventh fluid in a supercritical state may be supplied onto the sixth fluid, and the sixth fluid, along with the seventh fluid, may be removed. In an embodiment, the fourth cleaning solution, the fourth rinse solution, the sixth fluid, and the seventh fluid may be the same as the second cleaning solution 412, the second rinse solution 422, the second fluid 432, and the third fluid 433, respectively, described with reference to embodiments of FIGS. 12H to 12L. Process steps, which are similar to those in the previously-described embodiment, may not be described in much further detail for economy of description.

Referring to FIG. 12O, a liner insulating layer 153p may be formed to conformally cover the inner surface of the pixel isolation trench TR1. The liner insulating layer 153p may cover a top surface of the mask pattern 104. In an embodiment, the liner insulating layer 153p may be formed by depositing an insulating material of a uniform thickness on the entire top surface of the semiconductor substrate 100, in which the pixel isolation trench TR1 is formed. In an embodiment, the liner insulating layer 153p may be formed of or include at least one compound selected from, for example, silicon oxide, silicon nitride, and silicon oxynitride.

Referring to FIG. 12P, a conductive layer 151p may be formed to fill the pixel isolation trench TR1, in which the liner insulating layer 153p is provided. For example, the conductive layer 151p may be an undoped poly-silicon layer. In an embodiment, the conductive layer 151p may be formed by a layer-forming method (e.g., chemical vapor deposition (CVD) or atomic layer deposition (ALD) methods) having a good step coverage property.

Referring to FIG. 12Q, the conductive layer 151p may be etched to form the conductive pattern 151. A preliminary capping layer 155p may be formed on the conductive pattern 151 to fill a remaining portion of the pixel isolation trench TR1. In an embodiment, the preliminary capping layer 155p may be formed by a layer-forming method (e.g., CVD or ALD methods) having a good step coverage property.

Referring to FIG. 12R, a planarization process and a strip process may be performed to remove the mask pattern 104 and the sacrificial pattern 101. During the planarization process, the liner insulating layer 153p and the preliminary capping layer 155p may be partially removed to form the insulating pattern 153 and the capping pattern 155. Thus, the pixel isolation structure 150 may be formed in the pixel isolation trench TR1 in block S70. The planarization process may be performed to expose the first surface 100a of the semiconductor substrate 100. In an embodiment, the process of removing the mask pattern 104 and the sacrificial pattern 101 and exposing the first surface 100a of the semiconductor substrate 100 may include a wet etching process.

Thereafter, the photoelectric conversion regions 110 of the second conductivity type may be formed in the semiconductor substrate 100. The photoelectric conversion regions PD may be formed by injecting impurities, which are of the second conductivity type (e.g., n-type) different from the first conductivity type, into the semiconductor substrate 100. The photoelectric conversion regions 110 may be spaced apart from the first and second surfaces 100a and 100b of the semiconductor substrate 100.

Referring to FIG. 12S, MOS transistors constituting the readout circuits may be formed on (e.g., formed directly thereon) the first surface 100a of the semiconductor substrate 100. For example, the transfer gates TG may be formed in the pixel regions PR, respectively. The formation of the transfer gates TG may include patterning the semiconductor substrate 100 to form a gate recess region in each of the pixel regions PR, forming a gate insulating layer to conformally cover an inner surface of the gate recess region, and forming a gate conductive layer to fill the gate recess region, and patterning the gate conductive layer. Furthermore, when the gate conductive layer is patterned to form the transfer gates TG, the gate electrodes of the readout transistors may also be formed in the pixel regions PR, respectively.

After the formation of the transfer gates TG, the floating diffusion regions FD may be formed in portions of the semiconductor substrate 100 near the transfer gates TG. The floating diffusion regions FD may be formed by injecting impurities, which are of the second conductivity type, into the semiconductor substrate 100. In an embodiment, source/drain impurity regions of the readout transistors may be formed during the process of forming the floating diffusion regions FD.

The interlayer insulating layers 210 and the interconnection structures, such as the conductive lines 221 and the contact plugs 222 may be formed on the first surface 100a of the semiconductor substrate 100. The interlayer insulating layers 210 may be formed to cover the transfer and logic transistors. The interlayer insulating layers 210 may be formed of a material having a good gap-filling property and may have a substantially flat top surface.

The contact plugs 222, which are connected to the floating diffusion regions FD or readout transistors, may be formed in the interlayer insulating layers 210. The conductive lines 221 may be formed between the interlayer insulating layers 210. In an embodiment, the contact plugs 222 and the conductive lines 221 may be formed of or include at least one compound selected from, for example, copper (Cu), aluminum (Al), tungsten (W), titanium (Ti), molybdenum (Mo), tantalum (Ta), titanium nitride (TiN), tantalum nitride (TaN), zirconium nitride (ZrN), tungsten nitride (WN), and alloys thereof.

Referring back to FIG. 6, a thinning process of removing a portion of the semiconductor substrate 100 may be performed to reduce a vertical thickness of the semiconductor substrate 100. The thinning process may include grinding or polishing the second surface 100b of the semiconductor substrate 100 and performing an anisotropic or isotropic etching process. In an embodiment, the semiconductor substrate 100 may be inverted, for the thinning process.

Thereafter, the optically-transparent layer 30 may be formed on the second surface 100b of the semiconductor substrate 100. The formation of the optically-transparent layer 30 may include sequentially forming the color filters 303 and the micro lenses 307.

FIG. 13A is a graph showing the number of leaning issues per wafer versus a G-factor of an image sensor, in an experimental example.

### Experimental Example

The fabricating method described with reference to embodiments of FIGS. 8 to 12S was used to fabricate image sensors having various G-factors. In this fabrication process, the drying process to form the pixel isolation trench was performed using supercritical fluid, as described with reference to embodiments of FIGS. 12G to 12L.

FIG. 13A shows the number of leaning issues per wafer, measured from fabricated wafers. Here, the leaning issue may mean leaning of a portion of a semiconductor substrate provided between the pixel isolation structures.

As shown FIG. 13A, the image sensor according to an embodiment of the present inventive concept did not have any leaning issue in a G-factor range of 825 to 2200.

FIG. 13B is a graph showing the number of leaning issues per wafer versus a G-factor of an image sensor, in a comparative example.

### Comparative Example

Image sensors were fabricated by a similar method to the fabricating method described with reference to FIGS. 8 to 12S, but unlike embodiments described with reference to FIGS. 12G to 12L, a supercritical fluid was not used in a drying process for forming the pixel isolation trench. The drying process on the pixel isolation trench was performed, under the condition that the pixel isolation trench was filled with isopropyl alcohol of about 65° C., unlike the afore-described embodiments of the present inventive concept.

In the comparative example, the image sensors were fabricated to have various G-factors, and then, the number of leaning issues per wafer was measured. FIG. 13B shows the measurement result in the comparative example.

Referring to FIG. 13B, for the image sensor fabricated in the comparative example, the leaning issue was abruptly increased, when the G-factor had a value of 1200 or greater. In addition, for the image sensor fabricated in the comparative example, there was no leaning issue, when the G-factor had a value less than 1200.

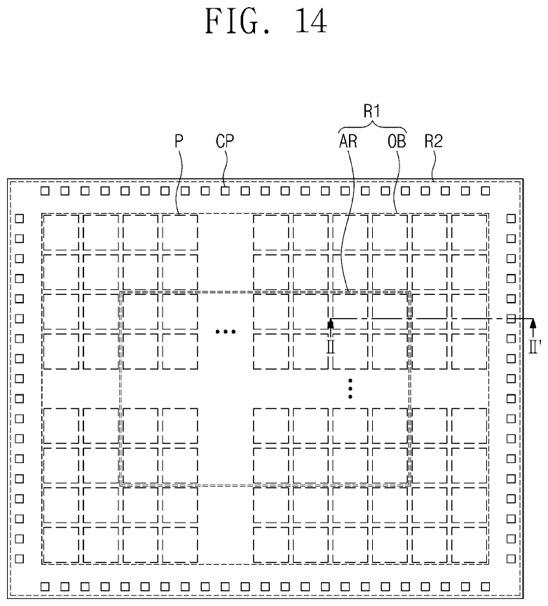

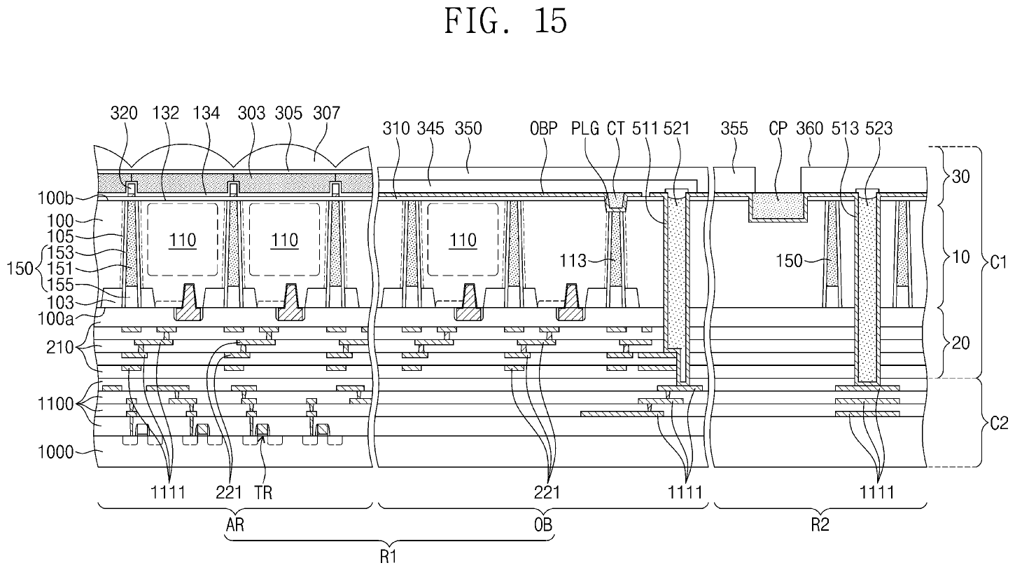

FIG. 14 is a plan view schematically illustrating an image sensor including a semiconductor device, according to an embodiment of the present inventive concept. FIG. 15 is a cross-sectional view which is taken along a line II-II′ of FIG. 14 to illustrate an image sensor according to an embodiment of the present inventive concept.

Referring to FIGS. 14 and 15, an image sensor may include a sensor chip C1 and a logic chip C2. The sensor chip C1 may include a pixel array region R1 and a pad region R2.

The pixel array region R1 may include a plurality of unit pixels P, which are two-dimensionally arranged in two different directions (e.g., in the first and second directions D1 and D2). Each of the unit pixels P may include a photoelectric conversion device and readout devices. An electrical signal, which is generated by an incident light, may be output from each of the unit pixels P of the pixel array region R1.

The pixel array region R1 may include a light-receiving region AR and a light-blocking region OB. The light-blocking region OB may be provided to enclose the light-receiving region AR, when viewed in a plan view. For example, the light-blocking region OB may be provided to enclose the light-receiving region AR in four different directions (e.g., up, down, left, and rights directions), when viewed in a plan view. In an embodiment, reference pixels, to which light is not incident, may be provided in the light-blocking region OB, and in this embodiment, by comparing a charge amount, which is obtained from the unit pixel P in the light-receiving region AR, with an amount of charges generated in the reference pixels, it may be possible to calculate a magnitude of an electrical signal sensed from the unit pixel P.

A plurality of conductive pads CP, which are used to input or output control signals and photoelectric signals, may be disposed in the pad region R2. The pad region R2 may be arranged to enclose the pixel array region R1, when viewed in a plan view, and in this embodiment, it may be possible to facilitate an electric connection between the image sensor and an external device. The conductive pads CP may transmit electrical signals, which are generated in the unit pixels P, to an external device.

In the light-receiving region AR, the sensor chip C1 may be configured to have the same technical features as the image sensor described above. For example, when viewed in the vertical direction, the sensor chip C1 may include the readout circuit layer 20, the optically-transparent layer 30, and the photoelectric conversion layer 10 therebetween, as described above, as described above. The photoelectric conversion layer 10 of the sensor chip C1 may include the semiconductor substrate 100, the pixel isolation structure 150 defining pixel regions, and the photoelectric conversion regions PD provided in the pixel regions, as described above. A pixel isolation structure 150 may have substantially the same structure on the light-receiving region AR and the light-blocking region OB.

The optically-transparent layer 30 may include a light-blocking pattern OBP, a back-side contact plug PLG, a contact pattern CT, a filtering layer 345, and a passivation layer 350 provided on the light-blocking region OB.

A portion of the pixel isolation structure 150 may be connected to the back-side contact plug PLG, in the light-blocking region OB.

For example, a semiconductor pattern 113 may be connected to the back-side contact plug PLG, in the light-blocking region OB. A negative bias may be applied to the semiconductor pattern 113 through the contact pattern CT and the back-side contact plug PLG. Accordingly, it may be possible to reduce a dark current which is generated at an interface between the pixel isolation structure 150 and the semiconductor substrate 100.

The back-side contact plug PLG may have a width that is larger than a width of the pixel isolation structure 150. The back-side contact plug PLG may be formed of or include at least one of metallic materials and/or metal nitride materials. For example, in an embodiment, the back-side contact plug PLG may be formed of or include at least one compound selected from titanium and titanium nitride.

The contact pattern CT may be buried in a contact hole, in which the back-side contact plug PLG is formed. The contact pattern CT may include a material that is different from the back-side contact plug PLG. For example, in an embodiment, the contact pattern CT may be formed of or include aluminum (Al).

The contact pattern CT may be electrically connected to the semiconductor pattern 113 of the pixel isolation structure 150. A negative bias may be applied to the semiconductor pattern 113 of the pixel isolation structure 150 through the contact pattern CT, and the negative bias may be delivered from the light-blocking region OB to the light-receiving region AR.

In the light-blocking region OB, the light-blocking pattern OBP may be continuously extended from the back-side contact plug PLG and may be disposed on a top surface of the planarization insulating layer 310. For example, the light-blocking pattern OBP may be formed of or include the same material as the back-side contact plug PLG. The light-blocking pattern OBP may be formed of or include at least one of metallic materials and/or metal nitride materials. For example, the light-blocking pattern OBP may be formed of or include at least one compound selected from titanium and titanium nitride. The light-blocking pattern OBP may not be extended to the light-receiving region AR of the pixel array region R1.

The light-blocking pattern OBP may prevent light from being incident into the photoelectric conversion regions PD, which are provided on the light-blocking region OB. The photoelectric conversion regions PD in the reference pixels of the light-blocking region OB may output a noise signal, not a photoelectric signal. The noise signal may be produced by electrons, which are generated by heat or a dark current.

A protection layer 355 may be extended from the pixel sensor array region R1 to the pad region R2. The protection layer 355 may be arranged to cover a top surface of the light-blocking pattern OBP.

A filtering layer 345 may be disposed on the light-blocking region OB to cover the protection layer 355. The filtering layer 345 may be configured to block light having a wavelength that is different from that by the color filters 303. For example, the filtering layer 345 may block infrared light. The filtering layer 345 may include a blue color filter. However, embodiments of the present inventive concept are not necessarily limited to this example.

An organic layer 355 and a passivation layer 360 may be disposed on a pad region to cover the light-blocking pattern OBP. In an embodiment, the organic layer 355 may be formed of or include the same material as micro lenses 340.

A first penetration conductive pattern 511 may be disposed in the light-blocking region OB to penetrate the semiconductor substrate 100 and may be electrically connected to a metal line 223 of the readout circuit layer 20 and an interconnection structure 1111 of the logic chip C2. The first penetration conductive pattern 511 may have a first bottom surface and a second bottom surface, which are located at various levels. A first gapfill pattern 521 may be disposed in the first penetration conductive pattern 511. In an embodiment, the first gapfill pattern 521 may be formed of or include at least one of low refractive materials and may have an insulating property.

The conductive pads CP may be disposed in portions of the semiconductor substrate 100 which are located in the pad region R2 and adjacent to the second surface 100b. The conductive pads CP may be buried in portions of the semiconductor substrate 100 located near the second surface 100b. In an embodiment, the conductive pads CP may be disposed in pad trenches, which are formed in the second surface 100b of the semiconductor substrate 100 and are located in the pad region R2. In an embodiment, the conductive pads CP may be formed of or include at least one metallic material (e.g., aluminum, copper, tungsten, titanium, tantalum, or alloys thereof). In a mounting process of an image sensor, bonding wires may be bonded to the conductive pads CP. The conductive pads CP may be electrically connected to an external device through bonding wires.

A second penetration conductive pattern 513 may be disposed on the pad region R2 to penetrate the semiconductor substrate 100 and may be electrically connected to the interconnection structure 1111 of the logic chip C2. The second penetration conductive pattern 513 may be extended to a region on the second surface 100b of the semiconductor substrate 100 and may be electrically connected to the conductive pads CP. A portion of the second penetration conductive pattern 513 may cover bottom and side surfaces of the conductive pads CP. A second gapfill pattern 523 may be provided in the second penetration conductive pattern 513. The second gapfill pattern 523 may be formed of or include at least one of low refractive materials and may have an insulating property. The pixel isolation structures 150 may be disposed on the pad region R2 to enclose the second penetration conductive pattern 513.

The logic chip C2 may include a logic semiconductor substrate 1000, logic circuits TR, the interconnection structures 1111 connected to the logic circuits TR, and logic interlayer insulating layers 1100. The uppermost layer of the logic interlayer insulating layers 1100 may be coupled to the readout circuit layer 20 of the sensor chip C1. The logic chip C2 may be electrically connected to the sensor chip C1 through the first and second penetration conductive patterns 511 and 513.

In an embodiment, the sensor and logic chips 1 and 2 are illustrated to be electrically connected to each other through the first and second penetration conductive patterns 511 and 513. However, embodiments of the present inventive concept are not limited to this example.

According to an embodiment of the present inventive concept, an image sensor may have a low process failure and a high pixel density and a method of fabricating the same.

While non-limiting embodiments of the present inventive concept have been particularly shown and described, it will be understood by one of ordinary skill in the art that variations in form and detail may be made therein without departing from the spirit and scope of the present inventive concept.

What is claimed is:

1. A method of fabricating an image sensor, comprising:
providing a semiconductor substrate having a first surface and a second surface that are opposite to each other;
forming a mask pattern on the first surface, the mask pattern having an opening;
supplying a first fluid in the opening;
vaporizing the first fluid to remove the first fluid on the semiconductor substrate;
performing an etching process using the mask pattern to form a pixel isolation trench extending from the first surface towards the second surface;
supplying a second fluid in the pixel isolation trench;
replacing the second fluid in the pixel isolation trench with a third fluid; and
vaporizing the third fluid,
wherein the third fluid has a surface tension that is lower than a surface tension of the first fluid.

2. The method of claim 1, wherein the vaporizing of the third fluid is performed under a pressure that is higher than a pressure for the vaporizing of the first fluid.

3. The method of claim 1, wherein the replacing of the second fluid with the third fluid comprises dissolving the second fluid in the third fluid.

4. The method of claim 1, wherein the vaporizing of the third fluid comprises:
applying a first pressure to the third fluid, the first pressure is higher than atmospheric pressure; and
applying a second pressure that is lower than the first pressure to the third fluid.

5. The method of claim 1, wherein the third fluid comprises carbon dioxide in a supercritical state.

6. The method of claim 1, wherein:
the first surface and the second surface are spaced apart from each other in a first direction; and
a length of the opening in the first direction is less than a length of the pixel trench.

7. The method of claim 1, further comprising loading the semiconductor substrate in a drying chamber before the replacing of the second fluid with the third fluid.

8. The method of claim 1, further comprising performing an ion implantation process in the pixel isolation trench.

9. The method of claim 1, further comprising performing an etching process on the mask pattern to increase a width of the opening.

10. The method of claim 1, wherein the second fluid includes isopropyl alcohol.

11. The method of claim 1, wherein the supplying of the second fluid is performed using a spin-on-process.

12. A method of fabricating an image sensor, comprising:
performing an etching process on a semiconductor substrate to form a pixel isolation trench that defines pixel regions;
performing a cleaning process using a cleaning solution in the pixel isolation trench;
removing the cleaning solution and supplying a first fluid in the pixel isolation trench;
loading the semiconductor substrate in a drying chamber and supplying a second fluid in a supercritical state onto the first fluid;
removing the first fluid and the second fluid in the pixel isolation trench by lowering an internal pressure of the drying chamber; and
performing an ion implantation process in the pixel isolation trench.

13. The method of claim 12, wherein the removing of the first fluid and the second fluid comprises dissolving the first fluid in the second fluid and vaporizing the second fluid.

14. The method of claim 13, further comprising exhausting the vaporized second fluid to an outside of the drying chamber.

15. The method of claim 12, wherein the second fluid comprises carbon dioxide in a supercritical state.

16. The method of claim 12, wherein the second fluid has a surface tension that is lower than a surface tension of the first fluid.

17. The method of claim 12, wherein the removing of the cleaning solution comprises supplying a rinse solution onto the semiconductor substrate using a spin-on-process.

18. An image sensor, comprising:
a semiconductor substrate having a first surface and a second surface that are opposite to each other in a first direction; and
a pixel isolation structure extending in the first direction between the first surface and the second surface to define a plurality of pixel regions,
wherein the pixel isolation structure comprises a first portion and a second portion that are spaced apart from each other with a first pixel region of the plurality of pixel regions interposed therebetween in a second direction perpendicular to the first direction, and
the image sensor has a G-factor in a range of about 1200 to about 2200, wherein the G-factor is determined by Formula 1,
G=(h⁴/t³d²), [Formula 1]
wherein G is the G-factor, h is a length of the first portion in the first direction, t is a distance between the first and second portions in the second direction, and d is a largest width of the first portion in the second direction.

19. The image sensor of claim 18, wherein the first portion and the second portion extend in a third direction to be parallel each other, the third direction is perpendicular to the second direction and parallel to the first surface.

20. The image sensor of claim 18, wherein a width of the first portion in the second direction decreases as a distance to the second surface decreases.
